(19) United States
(12) Patent Application Publication
(10) Pub. No.: US 2026/0229277 A1
(43) Pub. Date: Aug. 6, 2026

(54) SUB-WORD LINE DRIVER CIRCUITRY INCLUDING CHAIN OF TRANSISTORS TO REMOVE FLOATING WORD LINE STATES

(71) Applicant: Micron Technology, Inc., Boise, ID (US)

(72) Inventors: Tae Hyoung Kim, Boise, ID (US); Christopher J. Kawamura, Boise, ID (US)

(21) Appl. No.: 19/446,100

(22) Filed: Jan. 12, 2026

Related U.S. Application Data
(60) Provisional application No. 63/754,316, filed on Feb. 5, 2025.

(51) Int. Cl. G11C 11/408

(52) U.S. Cl. CPC G11C 11/4085

(57) ABSTRACT

A device comprises a number of sub-word line drivers and a chain of transistors. Each sub-word line driver includes a complementary pair of transistors coupled in parallel between a respective main word line and a respective word line. A first phase signal line is coupled to respective gates of respective N-type transistors of respective complementary pairs of transistors of the number of sub-word line drivers. A second phase signal line is coupled to respective gates of respective P-type transistors of the respective complementary pairs of transistors of the number of sub-word line drivers. Respective transistors of the chain of transistors are coupled between respective pairs of word lines of adjacent sub-word line drivers of the number of sub-word line drivers. The chain of transistors include a terminating transistor coupled between a first end word line of the number of word lines and a voltage line supplied with an inactive voltage.

### CROSS-REFERENCE TO RELATED APPLICATIONS

This application claims the benefit under 35 U.S.C. § 119(e) of U.S. Provisional Patent Application Ser. No. 63/754,316, filed Feb. 5, 2025. The subject matter of this application is related to U.S. patent application Ser. No. ______ (attorney docket No. 2269-P18148.1US), filed on even date herewith, the disclosure of each of which is hereby incorporated herein in its entirety by this reference.

### TECHNICAL FIELD

Examples of the disclosure relate to word line driver circuitry. More specifically, various examples relate to sub-word line driver circuitry including at least one chain of transistors to remove floating word line states of word lines, including related devices, methods, and systems.

### BACKGROUND

Memory devices are typically provided as internal, semiconductor, integrated circuits in computers or other electronic systems. There are many different types of memory including, for example, random-access memory (RAM), read only memory (ROM), dynamic random access memory (DRAM), synchronous dynamic random access memory (SDRAM), resistive random access memory (RRAM), double data rate memory (DDR), low power double data rate memory (LPDDR), phase change memory (PCM), and Flash memory.

Memory devices typically include many memory cells that are capable of holding a charge that is representative of a bit of data. Typically, these memory cells are arranged in a memory array. Data may be written to or retrieved from a memory cell by selectively activating the memory cell via an associated word line driver.

### BRIEF DESCRIPTION OF THE DRAWINGS

FIG. 1 is a schematic block diagram depicting a memory system, which may embody one or more examples of the disclosure;

FIG. 2 is a schematic block diagram depicting a memory device, which may embody sub-word driver (SWD) circuitry according to one or more examples;

FIG. 3 is a diagram of an SWD including a single driver transistor, which may be utilized in SWD circuitry of one or more examples;

FIG. 4 is a signal diagram of control signals, which may be used to control SWDs including a single transistor (e.g., the SWD of FIG. 3);

FIG. 5 is a schematic diagram of SWD circuitry including single transistor technology, which may be employed in one or more examples;

FIGS. 6A and 6B are schematic diagrams depicting SWD circuitry, which may be utilized in one or more examples;

FIG. 7A is a schematic diagram of SWD circuitry including at least one chain of transistors according to one or more examples of the disclosure;

FIG. 7B is a schematic diagram of the SWD circuitry of FIG. 7A indicating signal state changes of control signals for activation of a word line according to an example operating scenario;

FIG. 8A is a table indicating signal state changes on various lines of the SWD circuitry of FIGS. 7A and 7B;

FIG. 8B is a table indicating alternative signal state changes on the various lines of the SWD circuitry of FIGS. 7A and 7B;

FIG. 9 depicts a layout of the SWD circuitry of FIGS. 7A and 7B, according to one or more examples;

FIG. 10 is a flowchart of a method of removing floating word line states of word lines of the SWD circuitry, according to one or more examples;

FIG. 11 is a schematic diagram of (“mux style”) sub-word line driver circuitry, which may be utilized in SWD circuitry of one or more examples of the disclosure;

FIG. 12 is a signal diagram of control signals, which may be used to drive mux style sub-word line driver circuitry of the disclosure;

FIG. 13A is a schematic diagram of SWD circuitry including mux style sub-word line drivers and at least one chain of transistors, according to one or more examples;

FIG. 13B is a schematic diagram of SWD circuitry of FIG. 13A, indicating signal state changes of the control signals for activation of a word line, according to an example operating scenario;

FIG. 14 depicts a layout of SWD circuitry of FIGS. 13A and 13B, according to one or more examples;

FIG. 15 depicts a layout of SWD circuitry of FIGS. 13A and 13B, according to one or more examples;

FIG. 16 depicts a layout of SWD circuitry of FIGS. 13A and 13B, according to one or more examples;

FIG. 17 is a schematic diagram of SWD circuitry including mux style sub-word line drivers and at least one chain of transistors, according to one or more examples;

FIG. 18 depicts a layout of SWD circuitry of FIG. 17, according to one or more examples;

FIG. 19 is a schematic diagram of SWD circuitry including mux style sub-word line drivers and at least one chain of transistors, according to one or more examples;

FIG. 20 depicts a layout of SWD circuitry of FIG. 19, according to one or more examples;

FIG. 21 is a flowchart of a method of removing floating word line states of word lines of SWD circuitry according to one or more examples;

FIG. 22 is a simplified block diagram of a memory device according to one or more examples of the disclosure; and

FIG. 23 is a simplified block diagram of an electronic system according to one or more examples of the disclosure.

### DETAILED DESCRIPTION

Memory typically includes many memory cells arranged in a two-dimensional array of intersecting rows and columns. Data is written to or retrieved from the memory cells by selectively applying activation voltages to word lines (i.e., access lines) and bit lines (i.e., data lines). In general, word lines activate memory cells and bit lines provide data to or retrieve data from the activated memory cells. When memory access is desired, an activation voltage may be applied to a word line by a word line driver to enable a desired function (e.g., read or write) to be performed. More particularly, when an activation voltage (e.g., a high voltage) is applied via a word line, circuitry (e.g., a passgate transistor) in a memory cell may enable a bit line to write data to or retrieve data from the activated memory cell. When memory access is not needed, the word line driver may apply a deactivation voltage (e.g., a low voltage or ground voltage).

In some memory devices and systems, a number of sub-word line drivers each include a single (e.g., only one) transistor to drive the word lines. In the single-transistor, sub-word line driver circuitry, a transistor is coupled to a main word line signal which is driven by a main word line driver, and translated to a word line corresponding to a memory cell matrix. The transistor is coupled to a phase signal which selectively activates the transistor to couple the word line to the main word line signal via the transistor. For example, the word line may be included in a first set of word lines that are each coupled to the same main word line signal via a transistor of a corresponding sub-word line driver. A second set of word lines that correspond to the memory cell matrix may be coupled to a different main word line signal and interleaved with the word lines of the first set.

When one of the word lines in the first set is selected and fired (e.g., for memory operations), the other word lines in the first set may be floated. The word lines in the second set may be used to shield the floating, unselected word lines in the first set from the selected and fired word line in the first set. In at least some cases, however, potential memory array defects may cause some of the floating, unselected word lines to be sourced high enough to cause data corruption.

In other memory devices and systems, the number of sub-word line drivers each include a “mux style” transistor arrangement to drive the word lines. The mux style sub-word line drivers may experience the same or similar issues as the single-transistor technology, as well as other particular issues, relating to floating word line states.

One or more examples of the disclosure may be built upon, or based on, single-transistor, sub-word line driver circuitry, or variations thereof, to improve the performance, reliability, and/or efficiency of such circuitry. One or more other examples of the disclosure may be built upon, or based on, mux style sub-word line driver circuitry, or variations thereof, to improve the performance, reliability, and/or efficiency of such circuitry.

According to one or more examples of the disclosure, a chain of transistors is interconnected with word lines of sub-word line driver circuitry, and coupled to a voltage line supplied with an inactive voltage (e.g., a low voltage) associated with an inactive voltage state. In a specific, non-limiting example, the inactive voltage is a negative word line voltage. In the chain, a majority of the transistors are coupled between respective pairs of word lines associated with adjacent sub-word line drivers. In one or more examples, the chain of transistors may include at least one terminating transistor coupled between one of the word lines and the voltage line supplied with the negative word line voltage (e.g., at an end of the chain). For inactive word lines, the chain of transistors is set in an on state to maintain otherwise floating word line states at the negative word line voltage via the at least one terminating transistor. When a word line is activated, the chain of transistors is set in an off state to decouple word lines from the voltage line supplied with the negative word line voltage.

The memory devices and systems of the disclosure are primarily described in the context of devices incorporating DRAM storage media. Memory devices configured in accordance with other examples of the disclosure, however, may include other types of memory devices and systems incorporating other types of storage media, including PCM, SRAM, SDRAM, DDR SDRAM, SGRAM, FRAM, RRAM, MRAM, read only memory (ROM), erasable programmable ROM (EPROM), electrically erasable programmable ROM (EEROM), ferroelectric, magnetoresistive, and other storage media, including non-volatile (e.g., flash, NAND and/or NOR) storage media. Although various examples are described herein with reference to memory devices, the present disclosure is not so limited, and the examples may be generally applicable to microelectronic devices that may or may not include semiconductor devices and/or memory devices. A person skilled in the art will readily appreciate that the technology may have variations and that the technology may be practiced without use of several of the details in the examples described below.

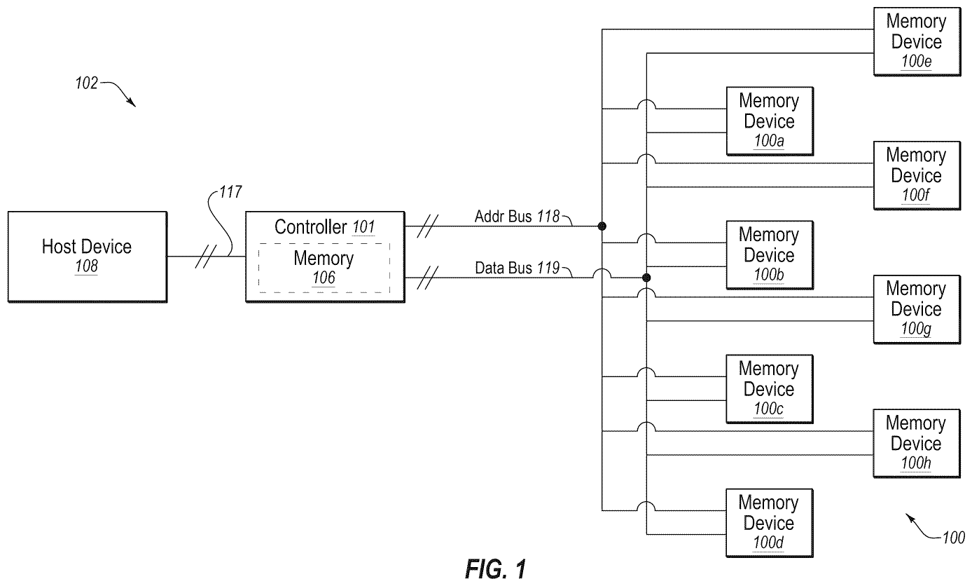

FIG. 1 is a schematic block diagram depicting a memory system 102, which may embody one or more examples of the disclosure. In one or more examples, memory system 102 is a dual in-line memory module (DIMM). Memory system 102 includes a number of memory devices 100 including memory devices 100a, 100b, 100c, 100d, 100e, 100f, 100g, and 100h. In one or more examples, memory devices 100 may be DRAM memory devices. Although illustrated with eight memory devices 100 in FIG. 1, memory system 102 may include a greater or lesser number of memory devices 100 in one or more other examples.

Memory devices 100 may be connected to one or more electronic devices that are capable of utilizing memory for temporary or persistent storage of information, or a component thereof. For example, one or more of memory devices 100 may be operably connected to one or more host devices. In a specific, non-limiting example, memory devices 100 of memory system 102 may be connected to a host device, such as a memory controller 101, which is connected to a host device 108.

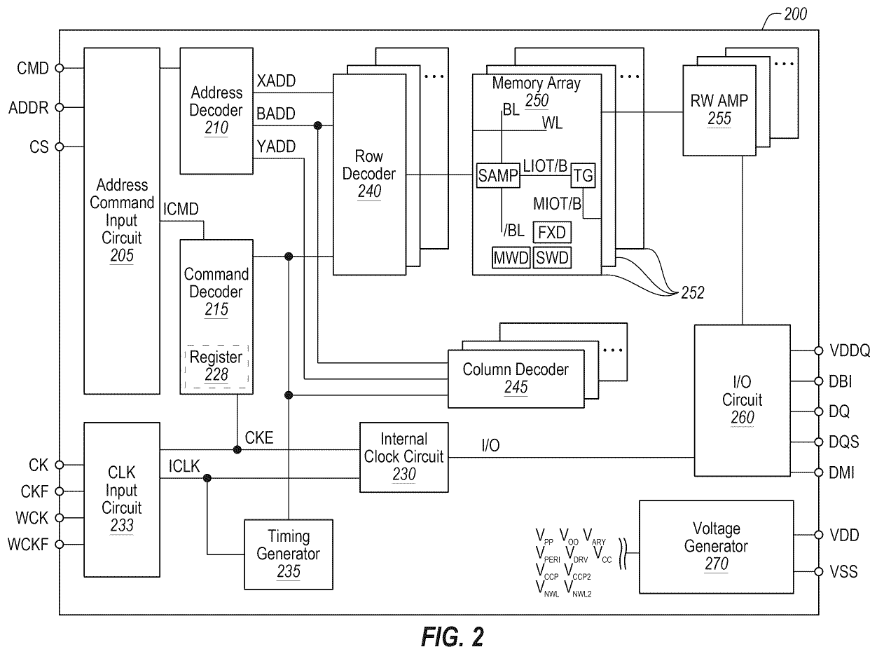

In one or more examples, memory devices 100 of FIG. 1 may be operably connected to memory controller 101 via a command/address (CMD/ADDR) bus 118 (hereinafter “address bus 118”) and a data (DQ) bus 119 (hereinafter “data bus 119”). As described in detail below, in relation to FIG. 2, address bus 118 and data bus 119 may be used by memory controller 101 to communicate commands, memory addresses, and/or data to memory devices 100. In response, memory devices 100 may execute commands received from memory controller 101. For example, in the event a write command is received from memory controller 101 over address bus 118, memory devices 100 may receive data from memory controller 101 over data bus 119 and may write the data to memory cells corresponding to memory addresses received from the memory controller 101 over address bus 118. As another example, in the event a read command is received from memory controller 101 over address bus 118, memory devices 100 may output data to memory controller 101 over data bus 119 from memory cells corresponding to memory addresses received from memory controller 101 over address bus 118.

In FIG. 1, memory controller 101 includes a memory 106 configured to store various processes, logic flows, and routines for controlling operation of memory system 102, including managing memory devices 100 and handling communications between memory devices 100 and host device 108. In one or more examples, memory 106 may include memory registers storing, for example, memory pointers, fetched data, etc. Memory 106 may also include read-only memory (ROM) or other non-volatile memory, and/or volatile memory (e.g., SRAM). Although shown embedded in memory controller 101 in FIG. 1, memory 106 may be positioned at other locations in memory system 102 in other examples of the disclosure, such as exterior memory controller 101, host device 108, and/or one or more of memory devices 100a, 100b, 100c, 100d, 100e, 100f, 100g, and 100h.

In one or more examples, host device 108 may be a computing device such as a desktop or portable computer, a server, a hand-held device (e.g., a mobile phone, a tablet, a digital reader, a digital media player), or some component thereof (e.g., a central processing unit, a co-processor, a dedicated memory controller, etc.). Host device 108 may be a networking device (e.g., a switch, a router, etc.); a recorder of digital images, audio, and/or video; a vehicle; an appliance; a toy; or any one of a number of other products. In one embodiment, host device 108 may be connected directly to one or more of memory devices 100 (e.g., via a communications bus of signal traces, not shown). Additionally, or alternatively, host device 108 may be indirectly connected to one or more of memory devices 100 (e.g., over a networked connection or through intermediary devices, such as through memory controller 101 and/or via a communications bus 117 of signal traces).

FIG. 2 is a schematic block diagram depicting a memory device 200, which may embody write driver circuitry according to one or more examples of the disclosure. Memory device 200 of FIG. 2 may be a specific example of any one of memory devices 100a, 100b, 100c, 100d, 100e, 100f, 100g, and 100h of FIG. 1. Memory device 200 may include an array of memory cells, such as a memory array 250. Memory array 250 may include a number of memory banks 252 (e.g., four banks, eight banks, sixteen banks, thirty-two banks, or any other number of memory banks), and each memory bank 252 may include a number of word lines (WLs), a number of bit lines (BLs), and a number of memory cells (e.g., m×n memory cells) arranged at intersections of the word lines (e.g., m word lines, which may also be referred to as memory rows) and the bit lines (e.g., n bit lines, which may also be referred to as memory columns). Memory array 250 (e.g., each memory bank 252) may be divided into smaller sections or subarrays, and the subarrays may be split into memory cell matrices (MATs). Memory cells of memory array 250 may include any one of a number of different memory media types, including capacitive, phase change, magnetoresistive, ferroelectric, or the like.

Memory array 250 further includes main word line drivers (MWDs) (also referred to herein as “global word line drivers”), sub-word line drivers (SWDs) (also referred to herein as “local word line drivers”), and phase drivers (FXDs). The MWDs, SWDs, and FXDs are coupled to corresponding word lines WLs, and are configured to control voltage levels on the corresponding word lines WLs during memory operations. For example, each word line WL may be coupled to one or more main rows or main word lines that are each driven by a corresponding MWD. More specifically, each main word line driven by a MWD may be coupled to eight SWDs, sixteen SWDs, or some other desired number of SWDs, and each of the SWDs and FXDs may be coupled to corresponding word lines WLs (e.g., local word lines) of one or more of the subarrays and/or one or more of the memory cell MATs of memory array 250. The SWDs may be used in combination with the MWDs and FXDs to control voltage levels on the corresponding word lines WLs. Along with the MWDs, the FXDs provide phase signals (PHs) to the SWDs to select SWDs for memory operations based on decoded row address signals and timing control signals.

The selection of a word line WL for memory operations may be performed by a row decoder 240, and the selection of a bit line BL (and/or a bit line/BL) for memory operations may be performed by a column decoder 245. In FIG. 2, row decoder 240 includes a respective row decoder for each memory bank 252, and column decoder 245 includes a respective column decoder for each memory bank 252. Sense amplifiers (SAMP) may be provided for corresponding bit lines BL and /BL, and may be connected to at least one respective local I/O line pair (LIOT/B) that, in turn, may be coupled to at least one respective main I/O line pair (MIOT/B) via transfer gates (TG) that may function as switches. Read data from the bit line BL or the bit line /BL is amplified by the sense amplifier SAMP, and transferred to read/write amplifiers 255 over the local I/O line pair, the transfer gates TG, and the main I/O line pair MIOT/B. Write data output from read/write amplifiers 255 is transferred to the sense amplifier SAMP over the main I/O line pair MIOT/B, the transfer gates TG, and the local I/O line pair LIOT/B, and thereafter written in or stored to a memory cell coupled to the bit line BL or the bit line /BL.

Memory device 200 may employ a number of external terminals that include command and address terminals coupled to a command/address bus (e.g., address bus 118 of FIG. 1) to receive command signals CMD and address signals ADDR, respectively. Memory device 200 may further include a chip select terminal to receive a chip select signal CS; clock terminals to receive clock signals CK and/or CKF; data clock terminals to receive data clock signals WCK, WCKF, and/or DQS; data terminals DQ, DBI (for data bus inversion function), and/or DMI (for data mask inversion function); and/or power supply terminals VDD, VSS, VDDQ, and/or VSSQ (not shown).

The power supply terminals may be supplied with power supply potentials VDD and VSS. These power supply potentials VDD and VSS may be supplied to an internal voltage generator circuit 270. Internal voltage generator circuit 270 may generate various internal potentials VPP, VOD, VARY, VPERI, VNWL, VNWL2, VDRV, VCC, VCCP, VCCP2, and the like, based on the power supply potentials VDD and VSS. In one or more examples, one or more of the internal potentials may be externally supplied to memory device 200, and/or some of the internal potentials may be generated by other circuits of memory device 200 (instead of voltage generator circuit 270) based on, for example, the power supply potentials VDD and VSS.

The internal potential VPP may be used in row decoder 240, the internal potentials VOD and VARY may be used in the sense amplifiers included in memory array 250, and the internal potential VPERI may be used in various circuit blocks of memory device 200. The negative word line voltage VNWL, the negative word line voltage VNWL2, the driver voltage VDRV, the common collector voltage VCC, the common collector pumped voltage VCCP, and/or the common collector pumped voltage VCCP2 may be used, for example, in memory array 250, such as by the MWDs, the SWDs, and/or the FXDs. In one or more examples, the common collector voltage VCC may be in a range from about 2.3 volts to 2.7 volts (e.g., 2.5 volts); the common collector pumped voltage VCCP may be in a range from about 3.0 volts to about 3.5 voltage (e.g., 3.3 volts); and the common collector pumped voltage VCCP2 may be in a range from about 4.0 volts to about 4.5 volts (e.g., 4.2 volts). In these and other embodiments, the driver voltage VDRV may be in a range from about 1.5 volts to about 2.0 volts (e.g., 1.9 volts), and the negative word line voltage VNWL may be in a range from about −0.1 volts to about −0.25 volts (e.g., −0.15 volts); the negative word line voltage VNWL2 may be made slightly lower than VNWL.

The power supply terminals may also be supplied with power supply potentials VDDQ and/or VSSQ (not shown). The power supply potentials VDDQ and VSSQ may be supplied to an input/output circuit 260 together with the power supply potentials VDD and VSS. The power supply potentials VDDQ and VSSQ may be the same potentials as the power supply potentials VDD and VSS, respectively, in some embodiments of the present technology. The power supply potentials VDDQ and VSSQ may be different potentials from the power supply potentials VDD and VSS, respectively, in other embodiments of the present technology. The power supply potentials VDDQ and VSSQ may be used for input/output circuit 260 so that power supply noise generated by input/output circuit 260 does not propagate to the other circuit blocks of memory device 200.

The external clock signals CK and CKF received at the clock terminals and/or the external data clock signals WCK and WCKF received at the data clock terminals may be supplied to a clock input circuit 233. For example, when enabled by a clock enable signal CKE, input buffers included in clock input circuit 233 may receive the clock signals CK and CKF and/or the data clock signals WCK and WCKF. The CK and CKF signals may be complementary, and/or the WCK and WCKF signals may be complementary.

Clock input circuit 233 may generate an internal clock signal ICLK based on the clock signals CK, CKF, WCK, and/or WCKF. The internal clock signal ICLK signal may be supplied to an internal clock circuit 230. In turn, internal clock circuit 230 may provide various phase and frequency controlled internal clock signals based on the internal clock signals ICLK and/or the clock enable signal CKE. The phase and frequency controlled internal clock signals may be used for timing operation of various internal circuits of memory device 200. For example, internal clock circuit 230 may provide input/output clock signals I/O to input/output circuit 260 of memory device 200. The input/output clock signals I/O may be used as timing signals for determining an output timing of read data and/or an input timing of write data. The input/output clock signals I/O may be provided at multiple clock frequencies so that data may be output from and/or input into memory device 200 at different data rates. A higher clock frequency may be desirable when high memory speed is desired. A lower clock frequency may be desirable when lower power consumption is desired. The internal clock signals ICLK may additionally or alternatively be supplied to a timing generator 235 (e.g., to generate various internal clock signals) and/or to a command decoder 215.

The command/address terminals may be supplied with addresses signals ADDR from outside memory device 200 (e.g., from a memory controller). The address signals ADDR supplied to the address terminals may be transferred, via command/address input circuit 205, to an address decoder 210. Address decoder 210 may receive the address signals ADDR and supply a decoded row address signal (XADD) to row decoder 240, and a decoded column address signal (YADD) to the column decoder 245. Address decoder 210 may also supply a decoded bank address signal (BADD) to row decoder 240 and to column decoder 245. The decoded bank address signal (BADD) may specify a memory bank 252 of memory array 250 containing the decoded row address XADD and the decoded column address YADD.

The command/address terminals may further be supplied with command signals CMD and/or chip select signals CS from outside memory device 200. The command signals may represent various memory commands (e.g., refresh commands; activate commands; precharge commands; access commands, such as read commands and write commands; timing commands; etc.) from a memory controller. The access commands may be associated with one or more row addresses XADD, column addresses YADD, and bank addresses BADD to indicate which memory cells of memory array 250 to access. The chip select signal CS may be used to select memory device 200 to respond to commands and addresses provided to the command and address terminals of memory device 200. When an active CS signal is provided to memory device 200, the commands and addresses may be decoded and memory operations may be performed. When the CS signal is not active, memory device 200 may ignore commands and/or addresses provided to the command and address terminals.

The command signals CMD received at the command terminals may be supplied to command decoder 215, via command/address input circuit 205, as internal command signals ICMD. Command decoder 215 may include circuits to decode the internal command signals ICMD and generate various internal signals and commands for performing memory operations. For example, command decoder 215 may provide a row command signal to select a word line and a column command signal to select a bit line (e.g., in response to receiving an access command). Other examples of memory operations that memory device 200 may perform based on decoding the internal command signals ICMD include refresh commands (e.g., re-establishing full charges stored in individual memory cells of memory array 250), activate commands (e.g., activating a row in a particular memory bank 252, in some cases for subsequent access operations), or precharge commands (e.g., deactivating the activated row in particular memory bank 252).

In one or more examples, command decoder 215 may further include one or more registers 228 for tracking various counts and/or values (e.g., counts of refresh commands received by memory device 200 or self-refresh operations performed by memory device 200) and/or for storing various operating conditions for memory device 200 to perform certain functions, features, and modes (or test modes). In one or more examples, registers 228 (or a subset of the registers 228) may be referred to as mode registers. Additionally, or alternatively, memory device 200 may include registers 228 as a separate component outside of command decoder 215. In one or more examples, registers 228 may include multi-purpose registers (MPRs) configured to write and/or read specialized data to and/or from memory device 200.

When a read command is issued to a memory bank 252 with an open row (i.e., a row selected for access) and a column address is timely supplied as part of the read command, read data may be read from memory cells in memory array 250 designated by the row address (which may have been provided as part of the activate command identifying the open row) and the column address. The read command may be received by command decoder 215, which may provide internal commands so that read data from memory array 250 is output from memory device 200 via read/write amplifiers 255 and input/output circuit 260, using the data terminals DQ, DBI, and/or DMI, and/or according to the DQS clock signal. The read data may be provided at a time defined by read latency information that may be programmed in memory device 200, for example, in a mode register (e.g., one or more of registers 228). The read latency information may be defined in terms of clock cycles of the CK clock signal. For example, the read latency information may be a number of clock cycles of the CK signal after the read command is received by memory device 200 when the associated read data is provided.

When a write command is issued to a memory bank 252 with an open row (i.e., a row selected for access) and a column address is timely supplied as part of the write command, write data may be supplied to the data terminals DQ, DBI, and/or DMI. The write data may be supplied to the data terminals DQ, DMI, and/or DMI according to the WCK and WCKF clock signals. The write command may be received by command decoder 215, which may provide internal commands to input/output circuit 260 so that the write data may be received by data receivers in input/output circuit 260, and supplied to memory array 250 via read/write amplifiers 255. The write data may be written in the memory cell designated by the row address and the column address. The write data may be provided to the data terminals at a time that is defined by write latency WL information. The write latency WL information may be programmed in memory device 200, for example, in a mode register (e.g., one or more of registers 228). The write latency WL information may be defined in terms of clock cycles of the CK clock signal. For example, the write latency information WL may be a number of clock cycles of the CK signal after the write command is received by the memory device 200 when the associated write data is received.

As described above, SWDs may be used in combination with MWDs to drive voltages onto word lines WLs for memory operations. For example, a two-transistor SWD may be coupled to a main word line signal that is driven by an MWD. When a word line WL corresponding to the SWD is selected for memory operations, a first transistor (e.g., a pull-up transistor) of the SWD may be activated to couple the word line WL to the main word line signal that ramps the voltage on the word line WL to a high voltage that is driven by the MWD. Activation of the first transistor may be controlled by a first FXD. When an adjacent word line WL (e.g., a word line WL of a same memory cell matrix) is selected, a second transistor (e.g., a pull-down transistor) of the SWD may be activated to couple the word line WL to a low voltage line to drop the voltage on the word line WL. Activation of the second transistor may be controlled by a second FXD. In other words, the SWD may be used to ramp the corresponding word line WL to a high voltage when the word line WL is selected for memory operations, and to drop the word line WL to a low voltage when adjacent local word lines are selected for memory operations.

The multiple transistor arrangement of the NMOS SWD consumes a relatively large amount of space, especially as the SWD is replicated for every word line across a memory array. Furthermore, the multiple transistor arrangement of the NMOS SWD utilizes multiple FXDs to selectively activate the transistors. Using multiple FXDs per SWD also consumes a relatively large amount space and a relatively large amount of power.

To address the above issues, memory devices and systems have been developed using NMOS sub-word line drivers having a single (e.g., only one) transistor. Such technology is described in application Ser. No. 17/894,089, filed on Aug. 23, 2022, published as US 2024/0071469 A1, portions of which are repeated herein for completeness. In one or more examples, the technology of the present disclosure is built upon, or based on, this single-transistor, sub-word line driver circuitry, or variations thereof, for improving the performance and/or reliability of such technology. In one or more other examples, the technology of the present disclosure may be built upon, or based on, a different type of sub-word line driver technology.

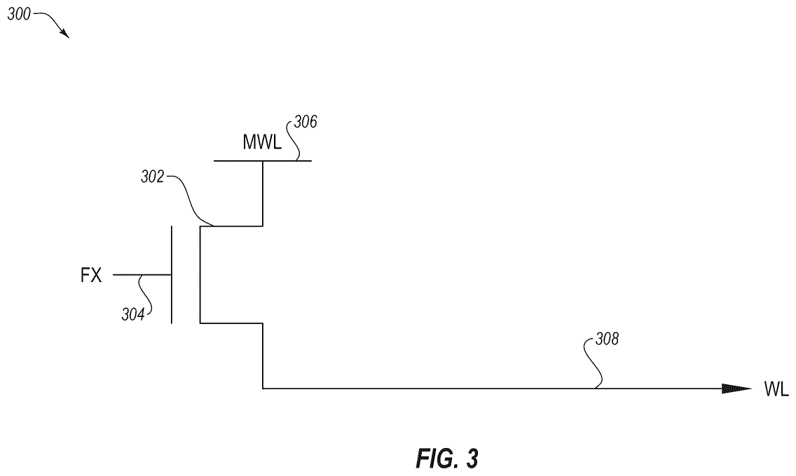

FIG. 3 is a diagram of an SWD 300 including a single NMOS transistor, which may be utilized in SWD circuitry of one or more examples of the disclosure. In the example of FIG. 3, SWD 300 includes a transistor 302. Transistor 302 of SWD 300 may be a single (e.g., and only) transistor of SWD 300. In one or more examples, transistor 302 may be an NMOS transistor. In FIG. 3, transistor 302 includes a first terminal (e.g., a source or a drain) coupled to a main word line 306 (MWL, or MWL 0/1), a second terminal (e.g., a drain or a source) coupled to a word line 308, and a gate coupled to a phase signal line (FX, or FX 0/1) 304 of a phase driver (FXD). Main word line 306 may be one of a first MWL (e.g., MWL0) or a second MWL (e.g., MWL1), and phase signal line 304 may be one of a first FX (e.g., FX0) or a second FX (e.g., FX2).

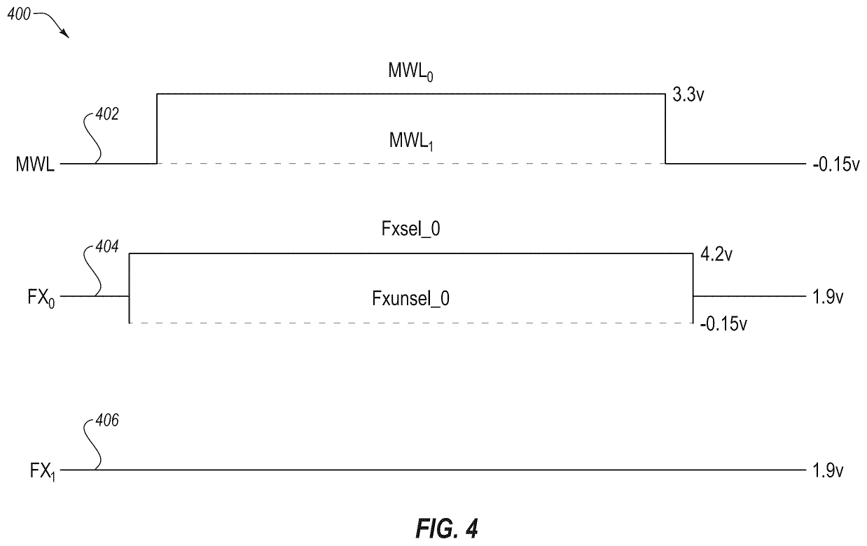

FIG. 4 is a signal diagram of control signals 400, which may be used to control SWDs including single transistor technology (e.g., SWD 300 of FIG. 3). Control signals 400 include MWL voltage signal levels 402 associated with MWL 306 of FIG. 3, phase signal voltage levels 404 (FX₀) associated with phase signal line 304 (or FX) of FIG. 3 when MWL 306 is in a high state, and a phase signal voltage level 406 (FX₁) associated with phase signal line 304 (or FX) of FIG. 3 when MWL 306 is in a low state. In the example of FIG. 4, MWL voltage signal levels 402 indicate a high state voltage of about 3.3 volts (e.g., associated with MWL0) and a low state voltage of about −0.15 volts (e.g., associated with MWL1). Phase signal voltage levels 404 (FX₀ or PH0) indicate a high state voltage (or “select”) of about 4.2 volts and a low state voltage (or “unselect”) of about −0.15 volts. Phase signal voltage level 406 (FX₁ or PH1) indicates a precharge voltage of about 1.9 volts.

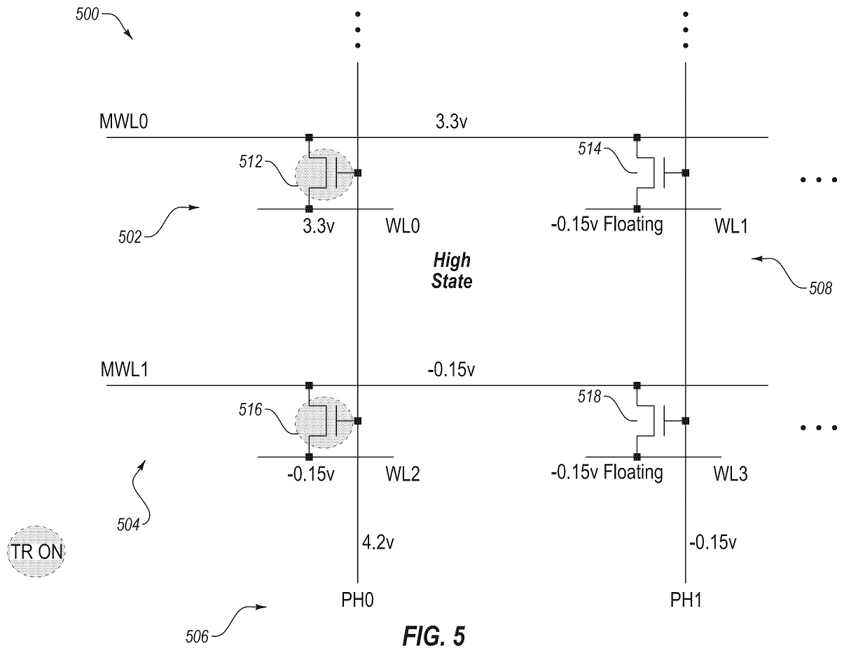

FIG. 5 is a schematic diagram of SWD circuitry 500 including single transistor technology, which may be utilized in one or more examples of the disclosure. SWD circuitry 500 includes a number of SWD transistors 502, a number of main word lines 504, a number of phase signal lines 506, and a number of word lines 508. The number of SWD transistors 502 includes SWD transistors 512, 514, 516, and 518. In one or more examples, each one of SWD transistors 502 may be the same or similar to SWD 300 including transistor 302 of FIG. 3 and/or controlled by control signals 400 of FIG. 4. The number of phase signal lines 506 includes a phase signal line PH0 and a phase signal line PH1. The number of main word lines 504 includes a main word line MWL0 and a main word line MWL1. MWL signals are doubled so that even and odd SWD gaps may be driven independently. The number of word lines 508 includes word lines WL0, WL1, WL2, and WL3.

In FIG. 5, a first terminal (e.g., a source or a drain) of SWD transistor 512 and a first terminal (e.g., a source or a drain) of SWD transistor 514 are coupled to main word line MWL0. A second terminal (e.g., a drain or a source) of SWD transistor 512 is coupled to word line WL0 and a second terminal (e.g., a drain or a source) of SWD transistor 514 is coupled to word line WL1. A first terminal (e.g., a source or a drain) of SWD transistor 516 and a first terminal (e.g., a source or a drain) of SWD transistor 518 are coupled to main word line MWL1. A second terminal (e.g., a drain or a source) of SWD transistor 516 is coupled to word line WL2 and a second terminal (e.g., a drain or a source) of SWD transistor 518 is coupled to word line WL3. A gate of SWD transistor 512 and a gate of SWD transistor 516 are coupled to phase signal line PH0. A gate of SWD transistor 514 and a gate of SWD transistor 518 are coupled to phase signal line PH1.

In FIG. 5, control signals are used to control SWD circuitry 500 to turn on SWD transistor 512 to set word line WL0 to a high state. To activate word line WL0, the main word line MWL0 is set to a high state (e.g., about 3.3 volts) and the main word line MWL1 is set to a low state (e.g., about −0.15 volts); the phase signal line PH0 is set to a high state (e.g., about 3.3 volts) and the phase signal line PH1 is set to a low state (e.g., about −0.15 volts). As the main word line MWL0 is at the high state and SWD transistor 512 is switched to turn on (PH0=high state), the word line WL0 is set to the high state voltage of the main word line MWL0. As the main word line MWL1 is at the low state and SWD transistor 516 is switched to turn on (PH0=high state), the word line WL2 is set to the low state voltage of the main word line MWL1. On the other hand, SWD transistor 514 and SWD transistor 518 remain off (PH1=low state) and therefore the word line WL1 and the word line WL3 remain floating at the low state (e.g., about −0.15 volts).

As is apparent, SWD transistor 512 is selectively activated in response to a high voltage on phase signal line PH0 when main word line MWL0 is at the high state. In this arrangement, only a single phase signal is utilized to activate SWD transistor 512. In comparison to SWDs having multiple transistor arrangements, SWDs having single transistor arrangements may have a relatively smaller footprint (e.g., through use of the single transistor and/or a single phase signal per sub-word line driver) and may consume less power (e.g., through use of the single phase signal per sub-word line driver). Such reduction in size improves array efficiency (AE) (i.e., a metric commonly used to evaluate at least some memory devices (e.g., DRAM devices)).

More generally, word lines of a memory cell matrix may be electrically coupled to one of two main word lines. For example, a first set of word lines may be coupled to a first main word line, and a second set of word lines may be coupled to a second main word line. Word lines of the first set may be interleaved with word lines of the second set in the memory cell mat. Using two main word lines instead of one main word line allows at least some unselected word lines of the memory cell matrix to be floated. More specifically, when a word line of one of the sets is selected and fired, the other word lines of that set may be floated, and word lines of the other set may be dropped to a low voltage to shield the floating word lines from coupling noise with the fired word line. Floating at least some of the unselected word lines rather than dropping all of the unselected word lines to a low voltage helps reduce the power consumed by a memory device incorporating such sub-word line drivers. It is desirable to ensure that the floating, unselected word lines are not adversely affected so as to cause data corruption.

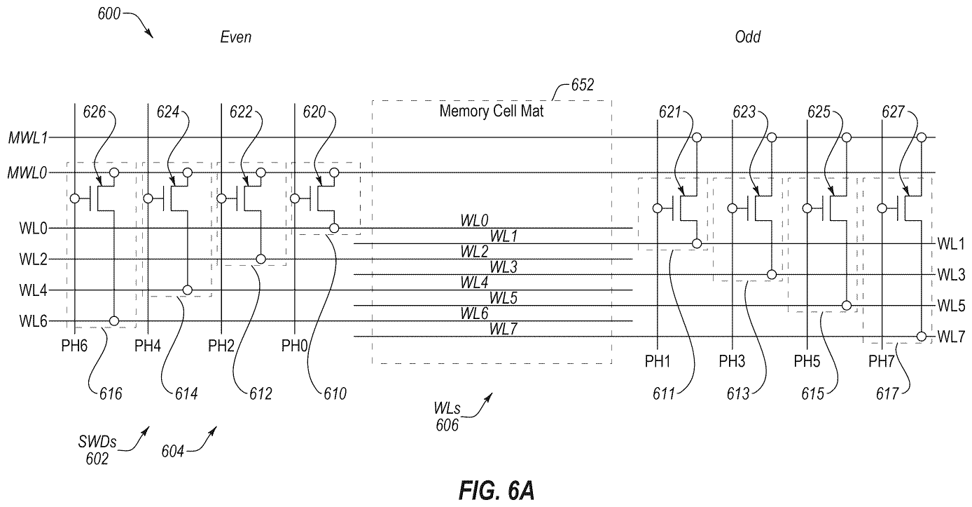

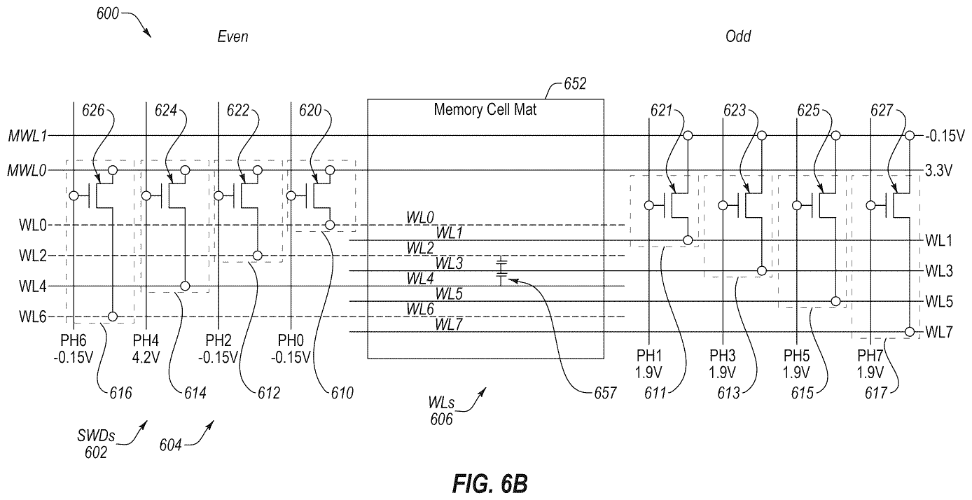

FIGS. 6A and 6B are schematic diagrams depicting SWD circuitry 600, which may be utilized in one or more examples of the disclosure. SWD circuitry 600 includes a number of sub-word line drivers (SWDs) 602. In FIG. 6A, the number of SWDs 602 includes SWDs 610, 612, 614, and 616 (i.e., even numbered SWDs) and SWDs 611, 613, 615, and 617 (i.e., odd numbered SWDs). As shown, each one of SWDs 602 is coupled to a corresponding one of a number of phase signal lines (PH) 604 and a corresponding one of a number of word lines (WLs) 606 of a memory cell MAT 652. The number of word lines 606 may be alternatively referred to as local word lines. In FIG. 6A, the number of word lines 606 includes WL0, WL2, WL4, and WL6 (i.e., even numbered word lines) and WL1, WL3, WL5, and WL7 (i.e., odd numbered word lines). Phase signal lines 604 include the phase signal lines PH0, PH2, PH4, and PH6 (i.e., even numbered phase signal lines) and PH1, PH3, PH5, and PH7 (i.e., odd numbered phase signal lines). Each of the phase signal lines PH0-PH7 may be driven by a corresponding phase driver FXD (not shown).

In one or more examples, the number of word lines 606 (e.g., WL0-WL7) terminates at or proximate memory cell MAT 652. Stated another way, word lines 606 do not pass through to the (global) memory array (e.g., memory array 250 of FIG. 2). As discussed above, such a configuration of word lines is easier and less costly to fabricate or manufacture than a pass-through configuration of word lines. In one or more alternative examples, the word lines may pass through to the memory array.

Each one of SWDs 602 may be further coupled to one of two main word lines MWL0 and MWL1. The main word lines may be alternatively referred to as global word lines. More specifically, SWDs 610, 612, 614, and 616 (i.e., even numbered SWDs) are each coupled to main word line MWL0, and SWDs 611, 613, 615, and 617 (i.e., odd numbered SWDs) are each coupled to the main word line MWL1. The main word lines may be driven by a corresponding main word line driver MWD (not shown). In one or more examples, the MWD that drives the main word line MWL0 may be different from the MWD that drives the main word line MWL1.

In one or more examples, the word lines WL0, WL2, WL4, and WL6 corresponding to SWDs 610, 612, 614, and 616, respectively, and to the main word line MWL0 are interleaved with the word lines WL1, WL3, WL5, and WL7 corresponding to SWDs 611, 613, 615, and 617, respectively, and to the main word line MWL1 in memory cell MAT 652. Stated another way, word lines from a first set comprising the word lines WL0, WL2, WL4, and WL6 alternate with word lines from a second set comprising the word lines WL1, WL3, WL5, and WL7, such that the word lines WL0, WL2, WL4, and WL6 of the first set are positioned every other word line in memory cell MAT 652. Stated even another way, the word lines WL0, WL2, WL4, and WL6 of the first set are interleaved with the word lines WL1, WL3, WL5, and WL7 of the second set, such that two of the word lines WL1, WL3, WL5, and WL7 of the second set (e.g., the word lines WL1 and WL3) flank opposite sides of one of the word lines WL0, WL2, WL4, and WL6 of the first set (e.g., the word line WL2) and are positioned immediately adjacent the one of the word lines WL0, WL2, WL4, and WL6 of the first set. In other words, the word lines WL0-WL7 of FIG. 6A are positioned in memory cell MAT 652 such that each of the word lines WL0, WL2, WL4, and WL6 of the first set are positioned immediately adjacent at least one of the word lines WL1, WL3, WL5, and WL7 of the second set, and vice versa. In one or more examples, the use of two main word lines and the interleaved positioning of the word lines WL0-WL7 may enable shielding of floating ones of the word lines WL0-WL7 while another one of the word lines WL0-WL7 is selected and fired.

SWDs 610-617 of FIG. 6A each include a single (e.g., only one) transistor 620-627. In one or more examples, each of SWDs 610-617 only includes a single transistor. In one or more examples, each of SWDs 610-617 includes a single transistor and may include other components (not shown) that are not transistors. In the example of FIG. 6A, transistors 620-627 are MOSFET transistors. In one or more examples, transistors 620-627 are NMOS transistors.

Referring to sub-word line driver 614 as an example, sub-word line driver 614 includes a single NMOS transistor 624. The NMOS transistor 624 includes a gate coupled to the phase signal line PH4 and configured to receive a phase voltage signal driven onto the phase signal line PH4 by a corresponding FXD (not shown). The NMOS transistor 624 further includes a source coupled to word line WL4 and a drain coupled to the main word line MWL0.

Again, use of a single transistor to selectively couple a corresponding word line to a corresponding global word line in each of sub-word line drivers 610-617 may reduce the amount of space occupied or consumed by each of the sub-word line drivers 610-617 in comparison to a sub-word line driver that includes multiple transistors to selectively couple a word line to a main word line. In one or more examples, the reduction of the footprints of the sub-word line driver 610-617 may contribute to realizing a smaller size (e.g., a smaller chip size) of the overall memory device (e.g., memory device 200 of FIG. 2). Additionally, or alternatively, use of a single transistor to selectively couple a corresponding word line to a corresponding main word line enables use of a single (e.g., only one) phase driver FXD to selectively activate the single transistor. Such a configuration may help reduce the power consumption of a memory device in comparison to memory devices employing sub-word line drivers that each incorporate multiple transistors and that are each coupled to multiple phase drivers to selectively activate those transistors. As the configuration utilizes a single FX signal per sub-word line driver, the size of memory array and/or the size of the overall memory device may be reduced in comparison to memory arrays and memory devices that employ multiple FX signals per sub-word line driver.

The selection of an SWD from SWDs 610-617, and thus a selection of a corresponding word line from the word lines WL0-WL7, is determined by the voltage driven onto the phase signal lines PH0-PH7 and the voltages driven onto the main word lines MWL0 and MWL1. Referring to sub-word line driver 614 again as an example, a voltage driven onto the phase signal line PH4 may be used to switch (e.g., selectively activate or deactivate) the NMOS transistor 624. As a specific example, the FXD corresponding to the phase signal line PH4 may set a voltage on the phase signal line PH4 at a low state (e.g., VNWL, VSS, VOFF, or another low voltage value), which may deactivate NMOS transistor 624 and leave the corresponding word line WL4 floating. As another specific example, the FXD corresponding to the phase signal line PH4 may set a voltage on the phase signal line PH4 at a high state (e.g., VCC, VCCP, VCCP2, or another high voltage value) or at an intermediate state (e.g., VDRV or another intermediate voltage value), which may activate NMOS transistor 624. When NMOS transistor 624 is activated, the voltage on the word line WL4 follows (e.g., is pulled up to, is pulled down to, or remains at) a voltage on the main word line MWL0. In some embodiments, the FXD may set the voltage on the phase signal line PH4 to the high state when the word line WL4 is selected and fired for memory operations, and may set the voltage on the phase signal line PH4 to the intermediate state when the word line WL4 (or other word lines coupled to the main word line MWL0) is used to shield floating words lines coupled to the main word line MWL1. The other sub-word line drivers 610-613 and 615-617 may be operated in a manner similar to and consistent with the discussion of sub-word line driver 614 above.

The voltages on the main word lines MWL0 and MWL1 may be set at a low state (e.g., VNWL, VSS, VOFF, or another low voltage value) or at a high state (e.g., VCC, VCCP, VCCP2, or another high voltage value). Thus, referring to sub-word line driver 614, when the voltage on the phase signal line PH4 is set at the high state or at the intermediate state, the voltage on the word line WL4 may be set at a low state (e.g., VNWL, VSS, VOFF, or another low voltage value) or at a high state (e.g., VCC, VCCP, VCCP2, or another high voltage value), depending on the voltage on the main word line MWL0. As discussed in greater detail below, the voltage on the word line WL4 may be set at the high state when the word line WL4 is selected and fired. When the word line WL4 is selected and fired (e.g., when transistor 624 is activated and a voltage on the word line WL4 is set at the high state), memory cells (not shown) corresponding to the word line WL4 may be accessed for memory operations (e.g., read, write, erase, refresh, etc.) based at least in part on the voltage on the main word line MWL0. Additionally, or alternatively, the voltage on the word line WL4 may be set at the low state, for example, when an adjacent word line (e.g., either the word line WL3 or the word line WL5) is selected and fired, and the word line WL4 is used to shield a floating word line (e.g., the other of the word line WL3 or the word line WL5 that is not selected and fired).

A method of operating sub-word line drivers 610-617 to select and fire the word line WL4 is now described in an example operating scenario. An initial state of the signals is first described. At a time t0, a voltage on each of the phase signal lines PH0-PH7 is initially set at an intermediate state (e.g., a voltage VDRV, or 1.9 volts). The voltage on each of the main word lines MWL0 and MWL1 is set at a low state (e.g., VNWL, or −0.15 volts). Setting the voltages on all of the phase signal lines PH0-PH7 to the intermediate state activates all of transistors 620-627 corresponding to sub-word line drivers 610-617. As such, the word lines WL0-WL7 are each coupled to a corresponding one of the main word lines MWL0 and MWL1 via a corresponding one of the transistors 620-627. In turn, the voltage on each of the word lines WL0-WL7 follows the voltage on the corresponding one of the main word lines MWL0 and MWL1. As mentioned above, the voltage on each of the main word lines MWL0 and MWL1 is set at the low state. As a result, the voltage on each of the word lines WL0-WL7 is also initially set at the low state (e.g., VNWL, or −0.15 volts).

At a time t1, the word line WL4 is selected for memory operations. In particular, the voltage on the phase signal line PH4 is ramped to a high state (e.g., VCCP2, or 4.2 volts) to activate transistor 624 of sub-word line driver 614 corresponding to the word line WL4. At the same time, the transistors of all other sub-word line drivers that are coupled to a same main word line as the sub-word line driver corresponding to the selected word line are deactivated. Thus, sub-word line drivers 610, 612, and 616 are each coupled to the same main word line (e.g., main word line MWL0) as sub-word line driver 614 that corresponds to the selected word line WL4. Therefore, in the illustrated example, the voltages on the phase signal lines PH0, PH2, and PH6 corresponding to sub-word line drivers 610, 612, and 616 are dropped to a low state (e.g., the voltage VNWL, or −0.15 volts) to deactivate transistors 620, 622, and 626.

The high voltage on the signal line PH4 keeps transistor 624 of sub-word line driver 614 activated such that the word line WL4 continues to follow the voltage on the main word line MWL0. The low voltages on the phase signal lines PH0, PH2, and PH6 deactivate transistors 620, 622, and 626, respectively, of sub-word line drivers 610, 612, and 616, respectively. Thus, the word lines WL0, WL2, and WL6 corresponding to the sub-word line drivers WL0, WL2, and WL6, respectively, are uncoupled from the main word line MWL0 and are left floating. The voltages on the phase signal lines PH1, PH3, PH5, and PH7 and the voltage on the main word line MWL1 (and therefore the voltages on the word lines WL1, WL3, WL5, and WL7) remain unchanged from time t0.

At a time t2, the voltage on the main word line (e.g., the main word line MWL0) corresponding to the selected word line (e.g., the word line WL4) is ramped to a high state (e.g., a voltage VCCP, or 3.1 volts). Because transistor 624 of sub-word line driver 614 is activated via the high voltage on the phase signal line PH4 such that the word line WL4 is coupled to the main word line MWL0 via transistor 624, the voltage on the word line WL4 follows the voltage on the main word line MWL0 from time t1 to a time t4. Thus, as the voltage on the main word line MWL0 is ramped to the high state at time t2, the voltage on the word line WL4 is also ramped to the high state (e.g., voltage VCCP, or 3.1 volts).

During time period between time t1 and time t4, the word lines WL0, WL2, and WL6 remain floating, so the voltages on those word lines do not change even as the voltage on the main word line MWL0 is ramped at time t2. In addition, the voltages on the phase signal lines PH1, PH3, PH5, and PH7 and the voltage on the main word line MWL1 remain unchanged. Thus, the voltages on the word lines WL1, WL3, WL5, and WL7 remain at the low state (e.g., VNWL, or −0.15 volts).

FIG. 6B is the schematic diagram of SWD circuitry 600 of FIG. 6A in a state of operation that corresponds to the time between time t2 and time t3 described above. As shown, the low voltages (e.g., VNWL, or −0.15 volts) on the phase signal lines PH0, PH2, and PH6 have deactivated transistors 620, 622, and 626, and have left the word lines WL0, WL2, and WL6 floating (as shown using dashed lines in FIG. 6B). In addition, the intermediate voltages (e.g., VDRV, or 1.9 volts) on the phase signal lines PH1, PH3, PH5, and PH7 have activated transistors 621, 623, 625, and 627, allowing the voltages on the word lines WL1, WL3, WL5, and WL7 to follow the voltage (e.g., VNWL, or −0.15 volts) on the main word line MWL1. Furthermore, the high voltage (e.g., VCCP2, or 4.2 volts) on the phase signal line PH4 has activated the transistor 624 of the sub-word line driver 614, coupling the word line WL4 to the main word line MWL0. Therefore, as the main word line MWL0 is ramped to the high state (e.g., VCCP, or 3.1 volts) at time t2, the voltage on the word line WL4 follows, and the word line WL4 is fired.

The word lines WL1, WL3, WL5, and WL7 that are coupled to the main word line MWL1 are interleaved with the word lines WL0, WL2, WL4, and WL6 that are coupled to the main word line MWL0. Thus, the word lines WL1, WL3, WL5, and WL7 are positioned immediately adjacent one of the floating word lines WL0, WL2, and WL6. In addition, each of the word lines WL1, WL3, WL5, and WL7 are positioned between at least one of the floating word lines WL0, WL2, and WL6 and the word line WL4. Such an arrangement allows the word lines WL1, WL3, WL5, and WL7 to shield immediately adjacent ones of the floating word lines WL0, WL2, and WL6 from coupling noise with the word line WL4 as the word line WL4 is fired (e.g., as the voltage on the word line WL4 is ramped to the high state, VCCP or 3.1 volts). For example, as the word line WL4 is fired, the word line WL3 (being at the low state, VNWL or −0.15 volts) may shield the floating word line WL2 from the word line WL4. More specifically, the word line WL3 may shield the floating word line WL2 from coupling noise caused, for example, by a parasitic capacitance 657.

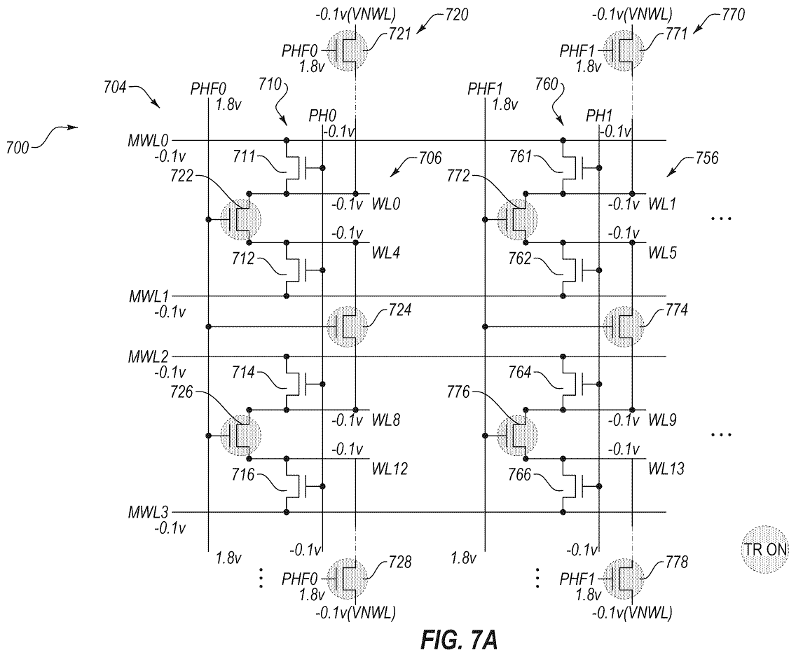

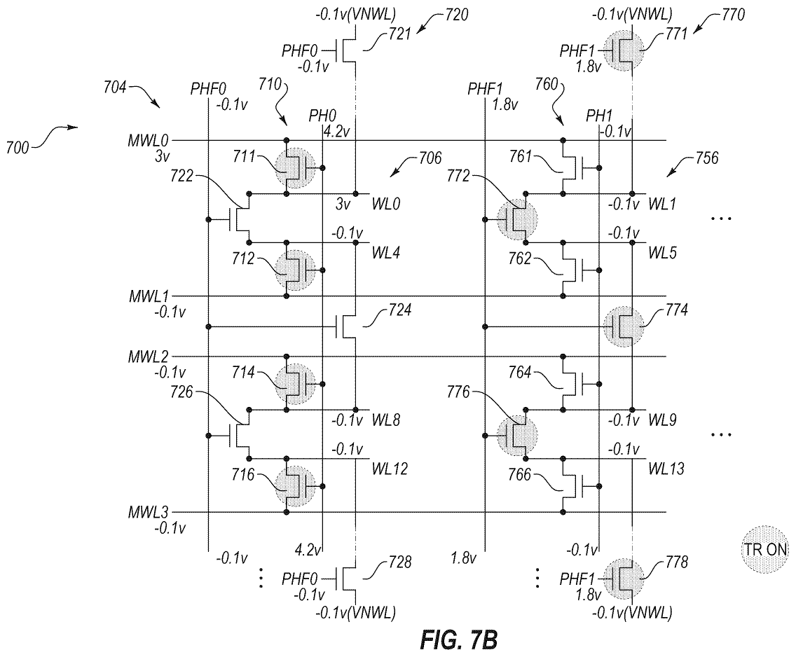

FIG. 7A is a schematic diagram of sub-word line driver (SWD) circuitry 700 including at least one chain of transistors, according to one or more examples. In FIG. 7A, SWD circuitry 700 includes a number of SWD transistors 710, a number of main word lines 704, a number of word lines 706, and a phase signal line PH0. The number of SWD transistors 710 includes SWD transistors 711, 712, 714, and 716. The number of main word lines 704 includes main word lines MWL0, MWL1, MWL2, and MWL3. The number of word lines 706 includes word lines WL0, WL4, WL8, and WL12.

SWD transistor 711 is coupled to main word line MWL0, SWD transistor 712 is coupled to main word line MWL1, SWD transistor 714 is coupled to main word line MWL2, and SWD transistor 716 is coupled to main word line MWL3. SWD transistor 711 is also coupled to word line WL0, SWD transistor 712 is also coupled to word line WL4, SWD transistor 714 is also coupled to word line WL8, and SWD transistor 716 is also coupled to word line WL12. Phase signal line PH0 is coupled to respective gates of SWD transistors 711, 712, 714, and 716. Respective ones of SWD transistors 711, 712, 714, and 716 are therefore driven by phase signal line PH0. In operation, respective ones of SWD transistors 711, 712, 714, and 716 are to connect respective word lines WL0, WL4, WL8, and WL12 to word line voltages on respective main word lines MWL0, MWL1, MWL2, and MWL3 in response to being turned on by phase signal line PH0. More specifically, SWD transistor 711 is to connect word line WL0 to a word line voltage on main word line MWL0 in response to being turned on (e.g., a high voltage) by phase signal line PH0. SWD transistor 712 is to connect word line WL4 to a word line voltage on main word line MWL1 in response to being turned on (e.g., a high voltage) by phase signal line PH0. SWD transistor 714 is to connect word line WL8 to a word line voltage on main word line MWL2 in response to being turned on (e.g., a high voltage) by phase signal line PH0. SWD transistor 716 is to connect word line WL12 to a word line voltage on main word line MWL3 in response to being turned on by phase signal line PH0. On the other hand, other SWD transistors of SWD circuitry 700 (e.g., an SWD transistor 761) are disabled in response to being turned off (e.g., a low voltage) by respective phase signal lines (e.g., a phase signal line PH1) so as to leave their associated word lines (e.g., a word line WL1) floating.

In one or more examples, SWD circuitry 700 further includes a number of SWD transistors 760, a number of word lines 756, and a phase signal line PH1. The number of SWD transistors 760 includes SWD transistors 761, 762, 764, and 766. The number of word lines 756 includes word lines WL1, WL5, WL9, and WL13. Additional SWD transistors, main word lines, and word lines may be included as indicated by the ellipsis points in FIG. 7A. Respective ones of SWD transistors 761, 762, 764, and 766 are driven by phase signal line PH1. SWD transistor 761 is associated with word line WL1, SWD transistor 762 is associated with word line WL5, SWD transistor 764 is associated with word line WL9, and SWD transistor 766 is associated with word line WL13.

SWD transistor 761 is coupled to main word line MWL0, SWD transistor 762 is coupled to main word line MWL1, SWD transistor 764 is coupled to main word line MWL2, and SWD transistor 766 is coupled to main word line MWL3. SWD transistor 761 is also coupled to word line WL1, SWD transistor 762 is also coupled to word line WL5, SWD transistor 764 is also coupled to word line WL9, and SWD transistor 766 is also coupled to word line WL13. Phase signal line PH1 is coupled to respective gates of SWD transistors 761, 762, 764, and 766. Respective ones of SWD transistors 761, 762, 764, and 766 are therefore driven by phase signal line PH1. In operation, respective ones of SWD transistors 761, 762, 764, and 766 are to connect respective word lines WL1, WL5, WL9, and WL13 to word line voltages on respective main word lines MWL0, MWL1, MWL2, and MWL3 in response to being turned on by phase signal line PH1. More specifically, SWD transistor 761 is to connect word line WL1 to a word line voltage on main word line MWL0 in response to being turned on by phase signal line PH1. SWD transistor 762 is to connect word line WL5 to a word line voltage on main word line MWL1 in response to being turned on by phase signal line PH1. SWD transistor 764 is to connect word line WL9 to a word line voltage on main word line MWL2 in response to being turned on by phase signal line PH1. SWD transistor 766 is to connect word line WL13 to a word line voltage on main word line MWL3 in response to being turned on by phase signal line PH1. On the other hand, other SWD transistors of SWD circuitry 700 (e.g., SWD transistor 711) are disabled in response to being turned off (e.g., a low voltage) by respective phase signal lines (e.g., phase signal line PH0) so as to leave their associated word lines (e.g., word line WL0) floating.

In one or more examples, SWD circuitry 700 includes a chain of transistors 720 associated with the number of SWD transistors 710. In FIG. 7A, the chain of transistors 720 includes transistors 721, 722, 724, 726, and 728. Respective ones of transistors 722, 724, and 726 in the chain of transistors 720 are coupled between respective pairs of word lines of adjacent ones of SWD transistors 710. For example, transistor 722 is coupled between word lines WL0 and WL4 of adjacent SWD transistors 711 and 712, transistor 724 is coupled between word lines WL4 and WL8 of adjacent SWD transistors 712 and 714, and transistor 726 is coupled between word lines WL8 and WL12 of adjacent SWD transistors 714 and 716.

The chain of transistors 720 are coupled to a voltage source. For example, the chain of transistors 720 may be coupled to a voltage source at a first (e.g., top) end and/or a second (e.g., bottom) end of the chain. In one or more examples, the voltage source is a low voltage source having an inactive voltage or a low voltage, such as a negative word line voltage (VNWL). Respective ones of transistors 721 and 728 may be referred to as terminating transistors. Transistor 721 is coupled between a first one of the number of word lines 706 (i.e., word line WL0) and a voltage line supplied with the negative word line voltage. Transistor 728 is coupled between a last one of the number of word lines 706 (i.e., word line WL12) and a voltage line supplied with the negative word line voltage.

A control signal line PHF0 is coupled to respective gates of respective transistors 721, 722, 724, 726, and 728 of the chain of transistors 720. Control signal line PHF0 is to provide an enable signal to set or maintain transistors 721, 722, 724, 726, and 728 in the chain of transistors 720 in an on state to couple the number of word lines 706 to the voltage lines supplied with the negative word line voltage (e.g., via transistor 721 and/or transistor 728). More particularly, control signal line PHF0 is to provide the enable signal to maintain transistors 721, 722, 724, 726, and 728 in the chain of transistors 720 in the on state while phase signal line PH0 provides a disable signal to set or maintain the number of transistors 710 in an off state. In one or more examples, control signal line PHF0 is to provide the enable signal to set or maintain the transistors in the chain of transistors 720 in the on state to maintain floating word lines at the negative word line voltage (e.g., via transistor 721 and/or transistor 728).

On the other hand, control signal line PHF0 is to provide a disable signal to set or maintain transistors 721, 722, 724, 726, and 728 in the chain of transistors 720 in an off state to decouple the number of word lines 706 from the voltage lines supplied with the negative word line voltage provided via transistor 721 and/or transistor 728. More particularly, control signal line PHF0 is to provide the disable signal to set or maintain transistors 721, 722, 724, 726, and 728 in the chain of transistors 720 in the off state while phase signal line PH0 provides an enable signal to set the number of transistors 710 in an on state (e.g., to activate one of the word lines).

In one or more examples, SWD circuitry 700 further includes a chain of transistors 770 associated with the number of SWD transistors 760. In FIG. 7A, the chain of transistors 770 includes transistors 771, 772, 774, 776, and 778. Respective ones of transistors 772, 774, and 776 in the chain of transistors 770 are coupled between respective pairs of word lines of adjacent ones of SWD transistors 760. For example, transistor 772 is coupled between word lines WL1 and WL5 of adjacent SWD transistors 761 and 762, transistor 774 is coupled between word lines WL5 and WL9 of adjacent SWD transistors 762 and 764, and transistor 776 is coupled between word lines WL9 and WL13 of adjacent SWD transistors 764 and 766.

The chain of transistors 770 are coupled to a voltage source. For example, the chain of transistors 770 may be coupled to a voltage source (e.g., the inactive voltage source or the low voltage source, such as the VNWL) at a first (e.g., top) end and/or a second (e.g., bottom) end of the chain. Respective ones of transistors 771 and 778 may be referred to as terminating transistors. Transistor 771 is coupled between a first one of the number of word lines 756 (i.e., word line WL1) and a voltage line supplied with the negative word line voltage. Transistor 778 is coupled between a last one of the number of word lines 756 (i.e., word line WL13) and a voltage line supplied with the negative word line voltage.

A control signal line PHF1 is coupled to respective gates of respective transistors 771, 772, 774, 776, and 778 of the chain of transistors 770. Control signal line PHF1 is to provide an enable signal to set or maintain transistors 771, 772, 774, 776, and 778 in the chain of transistors 770 in an on state to couple the number of word lines 756 to the voltage line supplied with the negative word line voltage (e.g., via transistor 771 and/or transistor 778). More particularly, control signal line PHF1 is to provide the enable signal to maintain transistors 771, 772, 774, 776, and 778 in the chain of transistors 770 in the on state while phase signal line PH1 provides a disable signal to set or maintain the number of transistors 760 in an off state. In one or more examples, control signal line PHF1 is to provide the enable signal to set or maintain the transistors in the chain of transistors 770 in the on state to maintain floating word lines at the negative word line voltage (e.g., via transistor 771 and/or transistor 778).

On the other hand, control signal line PHF1 is to provide a disable signal to set or maintain transistors 771, 772, 774, 776, and 778 in the chain of transistors 770 in an off state to decouple the number of word lines 756 from the voltage line supplied with the negative word line voltage provided via transistor 771 and/or transistor 778. More particularly, control signal line PHF1 is to provide the disable signal to set or maintain transistors 771, 772, 774, 776, and 778 in the chain of transistors 770 in the off state while phase signal line PH1 provides an enable signal to set the number of transistors 760 in an on state (e.g., to activate one of the word lines).

In FIG. 7A, respective ones of main word lines MWL0, MWL1, MWL2, and MWL3 are indicated to have a low voltage (e.g., −0.1 volts). Respective ones of SWD transistors 710 are indicated as driven at a low voltage (e.g., −0.1 volts) via phase signal line PH0. Respective ones of word lines WL0, WL4, WL8, and WL12 are indicated to therefore have a low voltage (e.g., −0.1 volts). Respective ones of transistors 721, 722, 724, 726, and 728 of the chain of transistors 720 are indicated as driven at a high voltage (e.g., 1.8 volts) via control signal line PHF0, and are therefore “on,” for coupling the word lines WL0, WL4, WL8, and WL12 to the voltage line supplied with the negative word line voltage via transistor 721 and/or transistor 728. Similarly, respective ones of SWD transistors 760 are indicated as driven at a low voltage (e.g., −0.1 volts) via phase signal line PH1. Respective ones of word lines WL1, WL5, WL9, and WL13 are indicated to therefore have a low voltage (e.g., −0.1 volts). Respective ones of transistors 771, 772, 774, 776, and 778 of the chain of transistors 770 are indicated as driven at a high voltage (e.g., 1.8 volts) via control signal line PHF1, and are therefore “on,” for coupling the word lines WL1, WL5, WL9, and WL13 to the voltage line supplied with the negative word line voltage via transistor 771 and/or transistor 778.

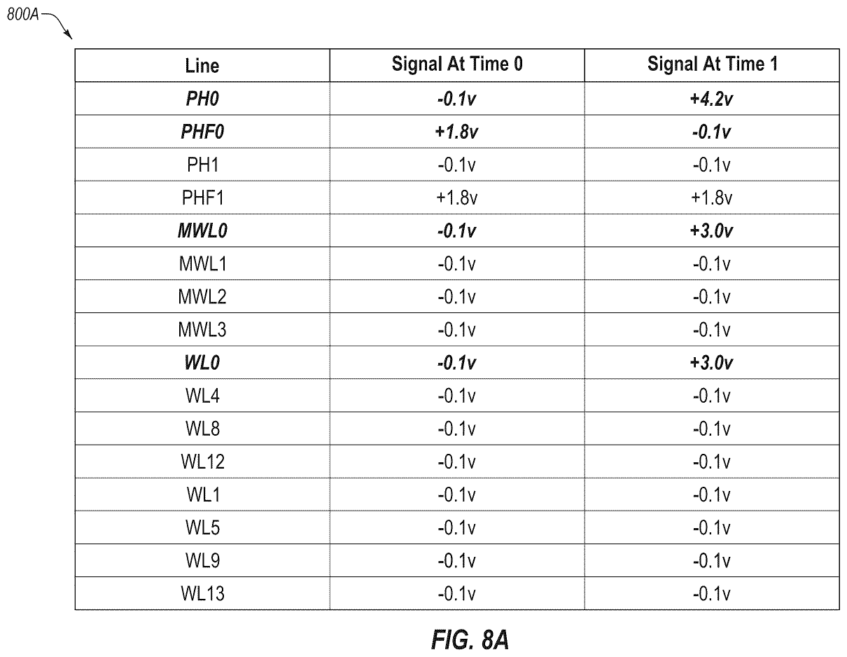

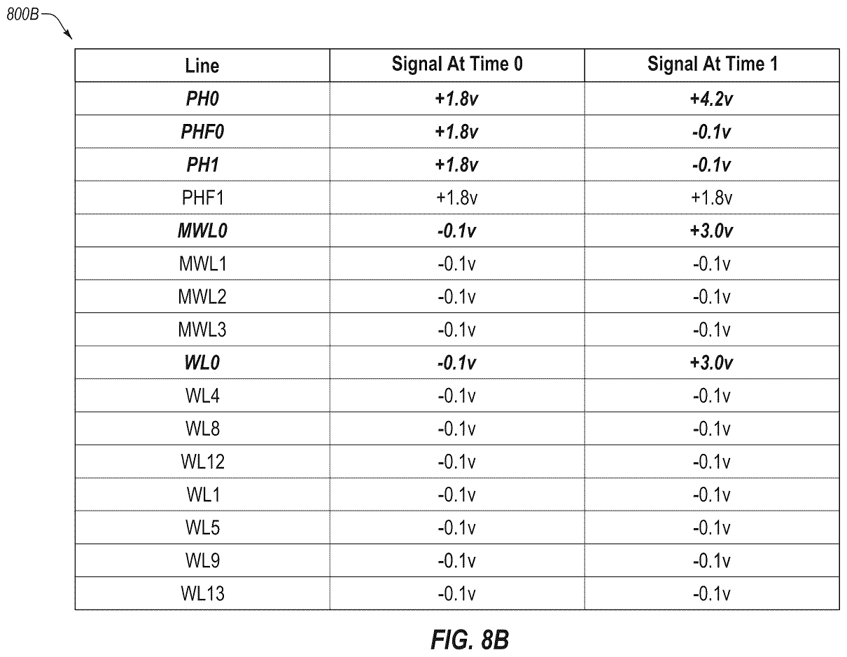

FIG. 7B is a schematic diagram of SWD circuitry 700 of FIG. 7A, indicating signal state changes of the control signals for activation of word line WL0 according to an example operating scenario. FIG. 8A is a table 800A indicating the signal state changes from time 0 to time 1 (indicated in bold italic text) on the various lines of SWD circuitry 700 of FIG. 7B.

In the example operating scenario of FIGS. 7B and 8A, phase signal line PH0 is set from a low voltage (e.g., −0.1 volts) (i.e., SWD transistors 710 being “off”) to a high voltage (e.g., 4.2 volts), turning “on” SWD transistors 710. Control signal line PHF0 is set from a high voltage (e.g., 1.8 volts) (i.e., chain of transistors 720 being “on”) to a low voltage (e.g., −0.1 volts), turning “off” chain of transistors 720. Main word line MWL0 is set from a low voltage (e.g., −0.1 volts) to a high voltage (e.g., 3.0 volts), and therefore word line WL0 is set to the high voltage (e.g., 3.0 volts). Word lines WL4, WL8, and WL12 remain at the low voltage (e.g., −0.1 volts) through main word lines MWL1, MWL2, and MWL3 at the low voltage, respectively. Control signal line PHF0 being set at the low voltage (e.g., −0.1 volts) turns “off” chain of transistors 720 to decouple word lines WL0, WL4, WL8, and WL12 from the voltage line supplied with the negative word line voltage provided via transistor 721 and/or transistor 728. Phase signal line PH1 remains at a low voltage (e.g., −0.1 volts) (i.e., SWD transistors 760 being “off”). Control signal line PHF1 remains at a high voltage (e.g., 1.8 volts) (i.e., chain of transistors 770 being “on”), keeping chain of transistors 770 “on” for continued coupling of word lines WL1, WL5, WL9, and WL13 to the voltage line supplied with the negative word line voltage via transistor 771 and/or transistor 778.

FIG. 8B is a table 800B indicating alternative signal state changes from time 0 to time 1 (indicated in bold italic text) on the various lines of SWD circuitry 700 of FIG. 7B. In the example operating scenario of FIGS. 7B and 8B, phase signal line PH0 is set from an intermediate voltage (e.g., 1.8 volts) (or precharge voltage) (i.e., SWD transistors 710 being in precharge state) to a high voltage (e.g., 4.2 volts), turning “on” SWD transistors 710. Control signal line PHF0 is set from the intermediate voltage (e.g., 1.8 volts) (or precharge voltage) (i.e., chain of transistors 720 being in precharge state) to a low voltage (e.g., −0.1 volts), turning “off” chain of transistors 720. Main word line MWL0 is set from a low voltage (e.g., −0.1 volts) to a high voltage (e.g., 3.0 volts), and therefore word line WL0 is set to the high voltage (e.g., 3.0 volts). Word lines WL4, WL8, and WL12 remain at the low voltage (e.g., −0.1 volts) through main word lines MWL1, MWL2, and MWL3 at the low voltage, respectively. Control signal line PHF0 being set at the low voltage (e.g., −0.1 volts) turns “off” chain of transistors 720 to decouple word lines WL0, WL4, WL8, and WL12 from the voltage line supplied with the negative word line voltage provided via transistor 721 and/or transistor 728. Phase signal line PH1 remains at a low voltage (e.g., −0.1 volts) (i.e., SWD transistors 760 being “off”). Control signal line PHF1 remains at a high voltage (e.g., 1.8 volts) (i.e., chain of transistors 770 being “on”), keeping chain of transistors 770 “on” for continued coupling of word lines WL1, WL5, WL9, and WL13 to the voltage line supplied with the negative word line voltage via transistor 771 and/or transistor 778.

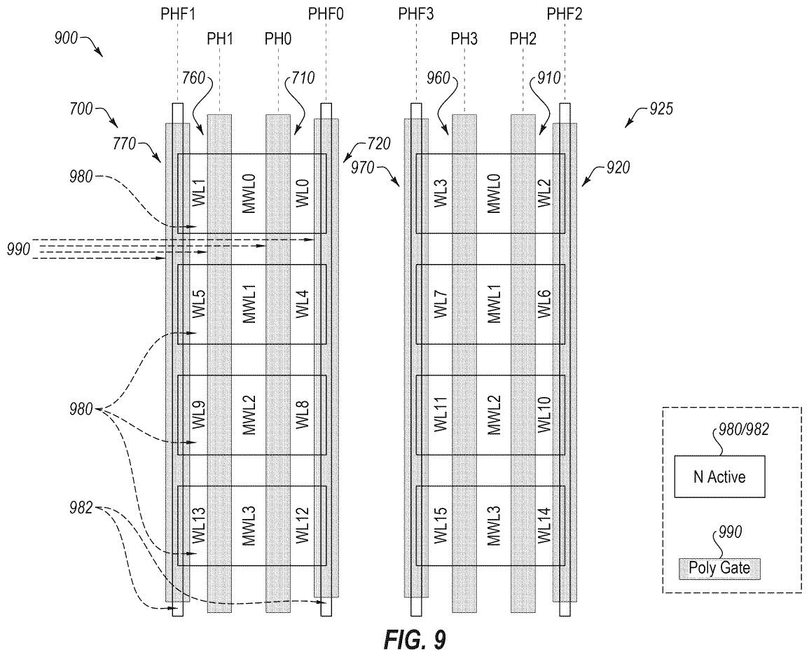

FIG. 9 depicts a layout 900 of SWD circuitry of FIGS. 7A and 7B, according to one or more examples. Layout 900 of FIG. 9 includes a layout portion associated with SWD circuitry 700 of FIG. 7A, which is on a left-hand side of FIG. 9. The layout portion of SWD circuitry 700 in FIG. 9 includes a number of active regions 980 (e.g., N active regions), a number of additional active regions 982 (e.g., N active regions), and a number of gate regions 990. Respective ones of active regions 980 (e.g., four (4) regions) are formed as horizontal or row-wise regions (with spacings or separations therebetween). Respective ones of gate regions 990 (e.g., four (4) regions) are formed as relatively narrow, vertical, or columnar regions (with spacings or separations therebetween). Respective ones of additional active regions 982 (e.g., two (2) regions) are also formed as relatively narrow, vertical, or columnar regions.

The gate region associated with phase signal line PH0 is formed to overlap the number of active regions 980, on middle-right sides of active regions 980, to form SWD transistors 710 (e.g., SWD transistors 710 including the SWD transistor coupled between main word line MWL0 and word line WL0, the SWD transistor coupled between main word line MWL1 and word line WL4, the SWD transistor coupled between main word line MWL2 and word line WL8, and the SWD transistor coupled between main word line MWL3 and word line WL12). The gate region and the additional active region associated with control signal line PHF0 are formed to overlap the number of active regions 980, on right-side edges of active regions 980, to form the chain of transistors 720 (e.g., chain of transistors 720 including the transistor coupled between the VNWL and the word line WL0, the transistor coupled between the word line WL0 and the word line WL4, the transistor coupled between the word line WL4 and the word line WL8, the transistor coupled between the word line WL8 and the word line WL12, and the transistor coupled between the word line WL12 and the VNWL).

The gate region associated with phase signal line PH1 is formed to overlap the number of active regions 980, on middle-left sides of active regions 980, to form SWD transistors 760 (e.g., SWD transistors 760 including the SWD transistor coupled between main word line MWL0 and word line WL1, the SWD transistor coupled between main word line MWL1 and word line WL5, the SWD transistor coupled between main word line MWL2 and word line WL9, and the SWD transistor coupled between main word line MWL3 and word line WL13). The gate region and the additional active region associated with control signal line PHF1 are formed to overlap the number of active regions 980, on left-side edges of active regions 980, to form the chain of transistors 770 (e.g., chain of transistors 770 including the transistor coupled between the voltage line supplied with VNWL and the word line WL1, the transistor coupled between the word line WL1 and the word line WL5, the transistor coupled between the word line WL5 and the word line WL9, the transistor coupled between the word line WL9 and the word line WL13, and the transistor coupled between the word line WL13 and the voltage line supplied with VNWL).

Layout 900 of FIG. 9 includes an additional layout portion associated with an SWD circuitry 925, which is on a right-hand side of FIG. 9. The additional layout portion of SWD circuitry 925 in FIG. 9 may comprise another half of the layout portion of SWD circuitry 700 (e.g., another half of SWD circuitry, which is not depicted in FIGS. 7A and 7B). Similar to the layout portion of SWD circuitry 700, the additional layout portion of SWD circuitry 925 in FIG. 9 includes a number of active regions, a number of additional active regions, and a number of gate regions. Respective ones of the active regions (e.g., four (4) regions) are formed as horizontal or row-wise regions (with spacings or separations therebetween). Respective ones of the gate regions (e.g., four (4) regions) are formed as relatively narrow, vertical, or columnar regions (with spacings or separations therebetween). Respective ones of the additional active regions (e.g., two (2) regions) are also formed as relatively narrow, vertical, or columnar regions.

The gate region associated with a phase signal line PH2 is formed to overlap the number of active regions, on middle-right sides of the active regions, to form SWD transistors 910 (e.g., SWD transistors 910 including the SWD transistor coupled between main word line MWL0 and a word line WL2, the SWD transistor coupled between main word line MWL1 and a word line WL6, the SWD transistor coupled between main word line MWL2 and a word line WL10, and the SWD transistor coupled between main word line MWL3 and a word line WL14). The gate region and the additional active region associated with a control signal line PHF2 are formed to overlap the number of active regions, on right-side edges of active regions, to form a chain of transistors 920 (e.g., the chain of transistors 920 including the transistor coupled between the voltage line supplied with VNWL and the word line WL2, the transistor coupled between the word line WL2 and the word line WL6, the transistor coupled between the word line WL6 and the word line WL10, the transistor coupled between the word line WL10 and the word line WL14, and the transistor coupled between the word line WL14 and the voltage line supplied with VNWL).

The gate region associated with a phase signal line PH3 is formed to overlap the number of active regions, on middle-left sides of active regions, to form SWD transistors 960 (e.g., SWD transistors 960 including the SWD transistor coupled between main word line MWL0 and a word line WL3, the SWD transistor coupled between main word line MWL1 and a word line WL7, the SWD transistor coupled between main word line MWL2 and a word line WL11, and the SWD transistor coupled between main word line MWL3 and a word line WL15). The gate region and the additional active region associated with a control signal line PHF3 are formed to overlap the number of active regions, on left-side edges of active regions, to form a chain of transistors 970 (e.g., the chain of transistors 970 including the transistor coupled between the voltage line supplied with VNWL and the word line WL3, the transistor coupled between the word line WL3 and the word line WL7, the transistor coupled between the word line WL7 and the word line WL11, the transistor coupled between the word line WL11 and the word line WL15, and the transistor coupled between the word line WL15 and the voltage line supplied with VNWL).

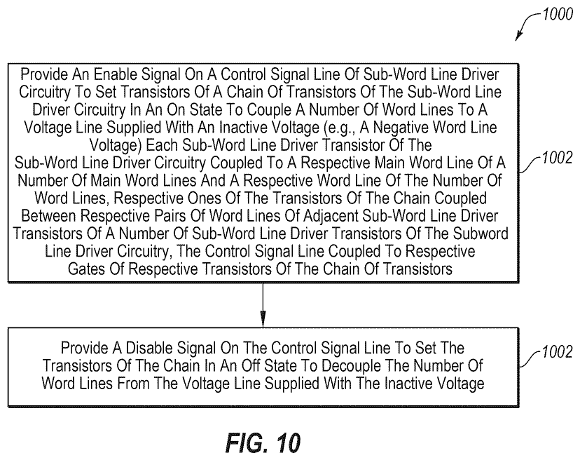

FIG. 10 is a flowchart of a method 1000 of removing floating word line states of word lines of SWD circuitry according to one or more examples. Method 1000 may be associated with use of SWD circuitry 700 of FIGS. 7A and 7B, arranged with or without layout 900 of FIG. 9, according to one or more examples.

Beginning at act 1002, an enable signal is provided on a control signal line of sub-word line driver circuitry to set transistors of a chain of transistors of the sub-word line driver circuitry in an on state. The setting of the transistors of the chain of transistors in the on state couples a number of word lines to a voltage line supplied with an inactive voltage (e.g., a negative word line voltage). In the sub-word line driver circuitry, each sub-word line driver transistor is coupled to a respective main word line of a number of main word lines and a respective word line of the number of word lines. Respective ones of the transistors of the chain are coupled between respective pairs of word lines of adjacent sub-word line driver transistors of a number of sub-word line driver transistors of the sub-word line driver circuitry. The control signal line is coupled to respective gates of respective transistors of the chain of transistors. At an act 1004, a disable signal is provided on the control signal line to set the transistors of the chain in an off state to decouple the number of word lines from the voltage line supplied with the inactive voltage.

In one or more examples of method 1000, in the act 1002, providing the enable signal on the control signal line to set the transistors of the chain of transistors in the on state to couple the number of word lines to the voltage line supplied with the inactive voltage is enabled via a terminating transistor coupled between one of the number of word lines and the voltage line supplied with the inactive voltage.

In one or more examples of method 1000, in the act 1002, providing the enable signal on the control signal line to set the transistors of the chain of transistors in the on state to couple the number of word lines to the voltage line supplied with the inactive voltage is performed while a phase signal line provides a disable signal to maintain respective transistors of the respective sub-word line drivers in an off state, the phase signal line coupled to respective gates of the respective transistors of respective sub-word line drivers of the number of sub-word line drivers.

In one or more examples of method 1000, a first word line is connected to an active word line voltage on a main word line at least partially responsive to turning on a first sub-word line driver transistor using a first phase signal line. Here, the first sub-word line driver transistor is coupled to the main word line having the active word line voltage. A second word line is floated at least partially responsive to turning off a second sub-word line driver transistor using a second phase signal line. Here, the second sub-word line driver transistor coupled to the main word line having the active word line voltage. The floating second word line is set at the negative word line voltage at least partially responsive to the coupling of the number of word lines to the voltage line supplied with the inactive voltage through the chain of transistors.

In one or more examples of the disclosure, the technology may improve the performance and/or reliability of single-transistor sub-word line driver circuitry or variations of such circuitry. The chain of transistors serve to maintain otherwise floating word lines at the low voltage to ensure that any memory array defects or other influences do not adversely affect the voltages on the word lines (e.g., causing data corruption). The use of transistors (e.g., in contrast to resistors) is advantageous for minimizing the amount of space utilized. The transistors may be easily accommodated in a layout using only a few additional gate regions and/or other regions.

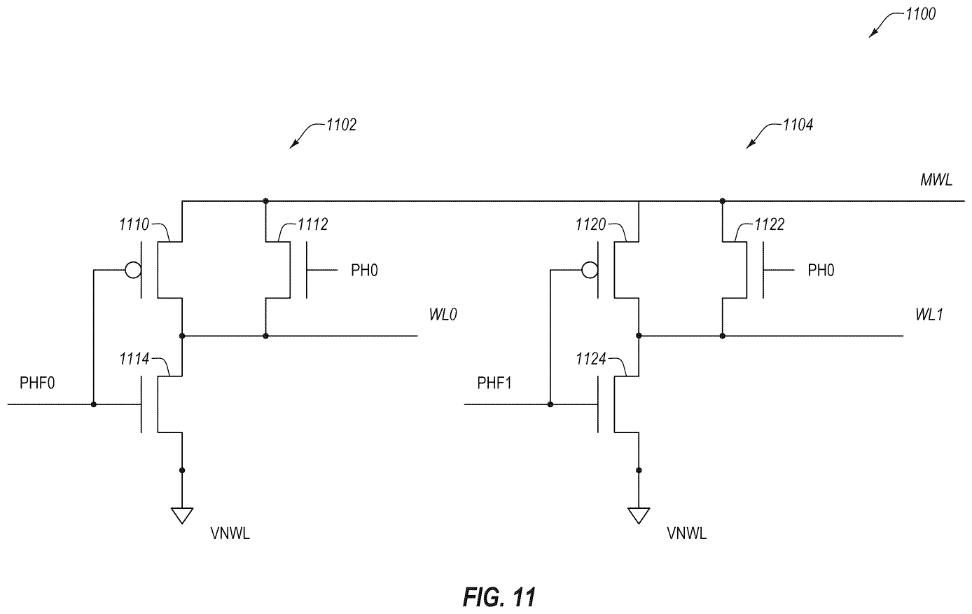

FIG. 11 is a schematic diagram of sub-word line driver circuitry 1100, which may be utilized in SWD circuitry of one or more examples of the disclosure. Sub-word line driver circuitry 1100 includes a sub-word line driver 1102 and a sub-word line driver 1104. Each one of sub-word line driver 1102 and sub-word line driver 1104 may be referred to herein as a “mux style sub word line driver.”

Sub-word line driver 1102, which is coupled to a word line WL0, includes transistors 1110, 1112, and 1114. In one or more examples, transistor 1110 is a PMOS transistor and transistors 1112 and 1114 are NMOS transistors. Sub-word line driver 1104, which is coupled to a word line WL1, includes transistors 1120, 1122, and 1124. In one or more examples, transistor 1120 is a PMOS transistor and transistors 1122 and 1124 are NMOS transistors.

With respect to sub-word line driver 1102, transistors 1110 and 1112 are a complementary pair of transistors coupled in parallel between a main word line MWL (e.g., a global word line) and word line WL0, with transistors 1110 and 1114 being coupled in series. More particularly, a drain of transistor 1110 (i.e., the p-type transistor) is coupled to main word line MWL, a source of transistor 1110 is coupled to word line WL0, and a gate of transistor 1110 is coupled to a phase signal line PHF0. In addition, a source of transistor 1112 (i.e., the n-type transistor) is coupled to main word line MWL, a drain of transistor 1112 is coupled to word line WL0, and a gate of transistor 1112 is coupled to a phase signal line PH0 (i.e., to provide a complement of phase signal PHF0). Further, a source of transistor 1114 is coupled to word line WL0, a drain of transistor 1114 is coupled to a negative word line voltage, and a gate of transistor 1114 is coupled to phase signal line PHF0.

With respect to sub-word line driver 1104, transistors 1120 and 1122 are a complementary pair of transistors coupled in parallel between main word line MWL (e.g., the global word line) and word line WL1, with transistors 1120 and 1124 being coupled in series. More particularly, a drain of transistor 1120 (i.e., the p-type transistor) is coupled to main word line MWL, a source of transistor 1120 is coupled to word line WL1, and a gate of transistor 1120 is coupled to a phase signal line PHF1. In addition, a source of transistor 1122 (i.e., the n-type transistor) is coupled to main word line MWL, a drain of transistor 1122 is coupled to word line WL1, and a gate of transistor 1112 is coupled to a phase signal line PH1 (i.e., to provide a complement of phase signal PHF1). Further, a source of transistor 1124 is coupled to word line WL1, a drain of transistor 1124 is coupled to the negative word line voltage, and a gate of transistor 1124 is coupled to phase signal line PHF1.

In an example operation, sub-word line driver 1102 may be in an active state (i.e., word line WL0 is selected) and sub-word line driver 1104 may be in an inactive state (i.e., word line WL1 is not selected). In such example operation, phase signal PHF0 is low (e.g., at −0.1 volts), phase signal PH0 is high (e.g., at 3 volts), transistors 1110 and 1112 are ON, transistor 1114 is OFF, and therefore word line WL0 is at a high voltage. In addition, phase signal PHF1 is high (e.g., at 3 volts), phase signal PH1 is low (e.g., at −0.1 volts), transistors 1120 and 1122 are OFF, transistor 1124 is ON, and therefore word line WL1 is at a low voltage (e.g., −0.1 volts).

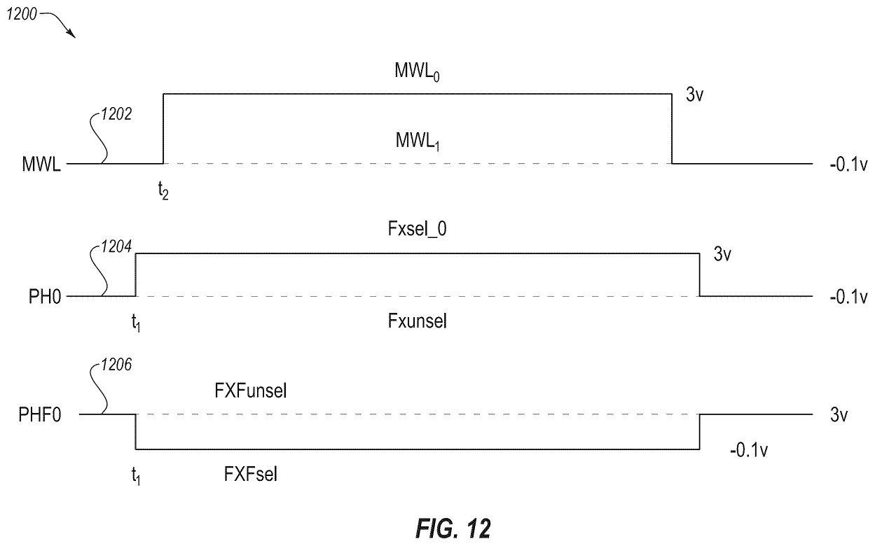

FIG. 12 is a signal diagram of control signals 1200 which may be used to control sub-word line driver circuitry including mux style sub-word line drivers (e.g., sub-word line driver circuitry 1100 of FIG. 11). Control signals 1200 include MWL voltage signal levels 1202 associated with main word line MWL of FIG. 11, phase signal voltage levels 1204 (PH0) associated with phase signal line PH0 of FIG. 11, and phase signal voltage levels 1206 (PHF0) associated with phase signal line PHF0 of FIG. 11. In the example of FIG. 12, each one of the signal levels exhibit a high state voltage of about 3 volts and a low state voltage of about −0.1 volts. In an example operation, at a time t1 (e.g., in response to an active command), the phase signal voltage on phase signal line PHF0 transitions to low and the phase signal voltage on phase signal line PH0 transitions to high. At a time t2, to initiate an active mode, the MWL voltage on main word line MWL transitions to high, thereby causing the WL voltage on word line WL0 to transition to high.

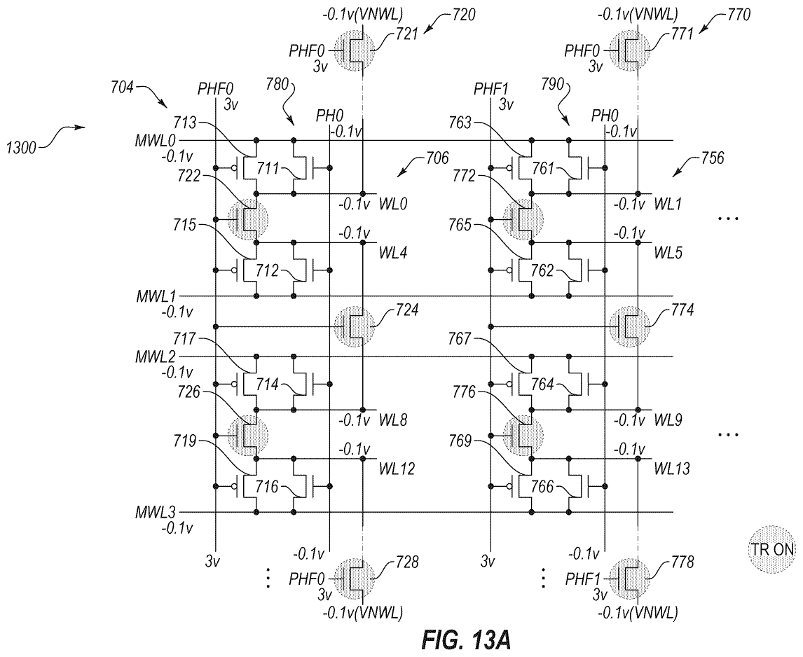

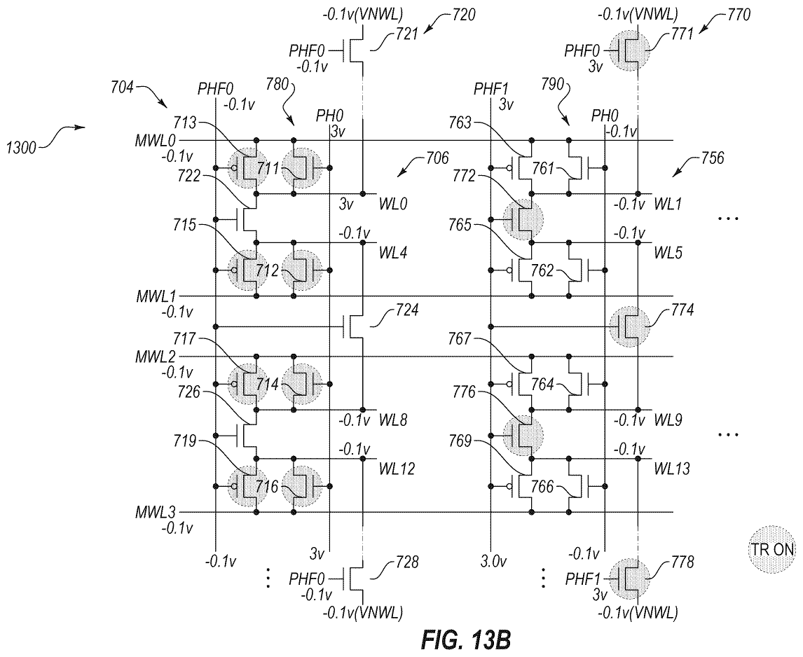

FIG. 13A is a schematic diagram of sub-word line driver (SWD) circuitry 1300 including mux style sub-word line drivers and at least one chain of transistors, according to one or more examples. SWD circuitry 1300 of FIG. 13A is based on, or built upon, SWD circuitry 700 of FIGS. 7A and 7B, but with use of “mux-style” sub-word line drivers (e.g., FIGS. 11 and 12) instead of the single SWD transistor drivers of FIGS. 7A and 7B.

More specifically, SWD circuitry 1300 includes a number of sub-word line drivers 780 of the “mux-style” type to respectively drive the number of word lines 706 (e.g., WL0, WL4, WL8, and WL12). Here, respective ones of the number of sub-word line drivers 780 include a p-type transistor (e.g., a PMOS transistor) (e.g., transistors 713, 715, 717, and 719 of the p-type) in addition to the existing n-type transistor (e.g., the NMOS transistor) (e.g., SWD transistors 711, 712, 714, and 716 of the n-type, now referred to simply as transistors 711, 712, 714, and 716). Thus, in the transistor driver configuration, respective ones of the number of sub-word line drivers 780 include a complementary pair of transistors (e.g., p-type and n-type transistors) coupled between a respective main word line of the number of main word lines 704 and a respective word line of the number of word lines 706. More specifically in FIG. 13A, a first sub-word line driver includes a complementary pair of transistors 713 and 711 coupled between the main word line MWL0 and the word line WL0, a second sub-word line driver includes a complementary pair of transistors 715 and 712 coupled between the main word line MWL1 and the word line WL4, a third sub-word line driver includes a complementary pair of transistors 717 and 714 coupled between the main word line MWL2 and the word line WL8, and a fourth sub-word line driver includes a complementary pair of transistors 719 and 716 is coupled between the main word line MWL3 and the word line WL12.

Phase signal line PH0 (previously referred to as control signal line PH0) is coupled to respective gates of respective (e.g., n-type) transistors 711, 712, 714, and 716 of the respective complementary pairs of transistors of the number of sub-word line drivers 780. In addition, phase signal line PHF0 is coupled to respective gates of respective (e.g., p-type) transistors 713, 715, 717, and 719 of the respective complementary pairs of transistors of the number of sub-word line drivers 780. Phase signal lines PH0 and PHF0 may provide complementary signals to the number of sub-word line drivers 780 (e.g., the same as or similar to phase signal voltage levels 1204 (PH0) and phase signal voltage levels 1206 (PHF0) of FIG. 12).

Thus, respective ones of the number of sub-word line drivers 780 are controlled by phase signal lines PH0 and PHF0. In operation, respective ones of the number of sub-word line drivers 780 are to connect respective word lines WL0, WL4, WL8, and WL12 to word line voltages on respective main word lines MWL0, MWL1, MWL2, and MWL3 in response to being turned on by phase signal lines PH0 and PHF0. More specifically, the first sub-word line driver including the complementary pair of transistors 713 and 711 is to connect word line WL0 to a word line voltage on main word line MWL0 in response to transistor 711 being turned on (e.g., a high voltage) by phase signal line PH0 and transistor 713 being turned on (e.g., a low voltage) by phase signal line PHF0. The second sub-word line driver including the complementary pair of transistors 715 and 712 is to connect word line WL4 to a word line voltage on main word line MWL1 in response to transistor 712 being turned on (e.g., a high voltage) by phase signal line PH0 and transistor 715 being turned on (e.g., a low voltage) by phase signal line PHF0. The third sub-word line driver including the complementary pair of transistors 717 and 714 is to connect word line WL8 to a word line voltage on main word line MWL2 in response to transistor 714 being turned on (e.g., a high voltage) by phase signal line PH0 and transistor 717 being turned on (e.g., a low voltage) by phase signal line PHF0. The fourth sub-word line driver including the complementary pair of transistors 719 and 716 is to connect word line WL12 to a word line voltage on main word line MWL3 in response to transistor 716 being turned on (e.g., a high voltage) by phase signal line PH0 and transistor 719 being turned on (e.g., a low voltage) by phase signal line PHF0.

Phase signal line PHF0 is coupled to respective gates of respective transistors 721, 722, 724, 726, and 728 of the chain of transistors 720. When the number of sub-word line drivers 780 are off or inactive, phase signal line PHF0 is to provide a first logic signal (e.g., high voltage) to set or maintain transistors 721, 722, 724, 726, and 728 in the chain of transistors 720 in an on state, to couple the number of word lines 706 to the voltage lines supplied with the negative word line voltage (e.g., via transistor 721 and/or transistor 728). In one or more examples, phase signal line PHF0 is to provide the first logic signal (e.g., high voltage) to set or maintain the transistors in the chain of transistors 720 in the on state to maintain floating word lines at the negative word line voltage (e.g., via transistor 721 and/or transistor 728). On the other hand, when one of sub-word line drivers 780 is turned on or active, phase signal line PHF0 is to provide a second logic signal (e.g., low voltage) to set or maintain transistors 721, 722, 724, 726, and 728 in the chain of transistors 720 in an off state to decouple the number of word lines 706 from the voltage lines supplied with the negative word line voltage provided via transistor 721 and/or transistor 728.

SWD circuitry 1300 further includes a number of sub-word line drivers 790 of the “mux-style” type to respectively drive the number of word lines 756 (e.g., WL1, WL5, WL9, and WL13). Here, respective ones of the number of sub-word line drivers 790 include a p-type transistor (e.g., PMOS transistor) (e.g., transistors 763, 765, 767, and 769 of the p-type) in addition to the existing n-type transistor (e.g., NMOS transistor) (e.g., SWD transistors 761, 762, 764, and 766) of the n-type, now referred to simply as transistors 761, 762, 764, and 766. Thus, in the transistor driver configuration, respective ones of the number of sub-word line drivers 790 include a complementary pair of transistors (e.g., p-type and n-type transistors) coupled between a respective main word line of the number of main word lines 704 and a respective word line of the number of word lines 756. More specifically in FIG. 13A, a fifth sub-word line driver includes a complementary pair of transistors 763 and 761 coupled between the main word line MWL0 and the word line WL1, a sixth sub-word line driver includes a complementary pair of transistors 765 and 762 coupled between the main word line MWL1 and the word line WL5, a seventh sub-word line driver includes a complementary pair of transistors 767 and 764 coupled between the main word line MWL2 and the word line WL9, and an eighth sub-word line driver includes a complementary pair of transistors 769 and 766 is coupled between the main word line MWL3 and the word line WL13.

Phase signal line PH1 (previously referred to as control signal line PH1) is coupled to respective gates of respective (e.g., n-type) transistors 761, 762, 764, and 766 of the respective complementary pairs of transistors of the number of sub-word line drivers 790. In addition, phase signal line PHF1 is coupled to respective gates of respective (e.g., p-type) transistors 763, 765, 767, and 769 of the respective complementary pairs of transistors of the number of sub-word line drivers 790. Phase signal lines PH1 and PHF1 may provide complementary signals to the number of sub-word line drivers 780 (e.g., the same as or similar to phase signal voltage levels 1204 (PH0) and phase signal voltage levels 1206 (PHF0) of FIG. 12).

Thus, respective ones of the number of sub-word line drivers 790 are controlled by phase signal lines PH1 and PHF1. In operation, respective ones of the number of sub-word line drivers 790 are to connect respective word lines WL1, WL5, WL9, and WL13 to word line voltages on respective main word lines MWL0, MWL1, MWL2, and MWL3 in response to being turned on by phase signal lines PH1 and PHF1. More specifically, the fifth sub-word line driver including the complementary pair of transistors 763 and 761 is to connect word line WL1 to a word line voltage on main word line MWL0 in response to transistor 761 being turned on (e.g., a high voltage) by phase signal line PH1 and transistor 763 being turned on (e.g., a low voltage) by phase signal line PHF1. The sixth sub-word line driver including the complementary pair of transistors 765 and 762 is to connect word line WL5 to a word line voltage on main word line MWL1 in response to transistor 762 being turned on (e.g., a high voltage) by phase signal line PH1 and transistor 765 being turned on (e.g., a low voltage) by phase signal line PHF1. The seventh sub-word line driver including the complementary pair of transistors 767 and 764 is to connect word line WL9 to a word line voltage on main word line MWL2 in response to transistor 764 being turned on (e.g., a high voltage) by phase signal line PH1 and transistor 767 being turned on (e.g., a low voltage) by phase signal line PHF1. The eighth sub-word line driver including the complementary pair of transistors 769 and 766 is to connect word line WL13 to a word line voltage on main word line MWL3 in response to transistor 766 being turned on (e.g., a high voltage) by phase signal line PH1 and transistor 769 being turned on (e.g., a low voltage) by phase signal line PHF1.

Phase signal line PHF1 is coupled to respective gates of respective transistors 771, 772, 774, 776, and 778 of the chain of transistors 770. When the number of sub-word line drivers 790 are off or inactive, phase signal line PHF1 is to provide a first logic signal (e.g., high voltage) to set or maintain transistors 771, 772, 774, 776, and 778 in the chain of transistors 770 in an on state, to couple the number of word lines 756 to the voltage lines supplied with the negative word line voltage (e.g., via transistor 771 and/or transistor 778). In one or more examples, phase signal line PHF1 is to provide the first logic signal (e.g., high voltage) to set or maintain the transistors in the chain of transistors 770 in the on state to maintain floating word lines at the negative word line voltage (e.g., via transistor 771 and/or transistor 778). On the other hand, when one of sub-word line drivers 790 is turned on or active, phase signal line PHF1 is to provide the second logic signal (e.g., low voltage) to set or maintain transistors 771, 772, 774, 776, and 778 in the chain of transistors 770 in an off state to decouple the number of word lines 756 from the voltage lines supplied with the negative word line voltage provided via transistor 771 and/or transistor 778.

In FIG. 13A, respective ones of main word lines MWL0, MWL1, MWL2, and MWL3 are indicated to have a low voltage (e.g., −0.1 volts). In addition, respective ones of the number of sub-word line drivers 780 are indicated as off or inactive as controlled by phase signal line PH0 (e.g., at −0.1 volts) and phase signal line PHF0 (e.g., at 3 volts). Respective ones of word lines WL0, WL4, WL8, and WL12 are therefore indicated to have a low voltage (e.g., −0.1 volts). Respective ones of transistors 721, 722, 724, 726, and 728 of the chain of transistors 720 are indicated as driven at a high voltage (e.g., 3 volts) by phase signal line PHF0, and are therefore on for coupling the word lines WL0, WL4, WL8, and WL12 to the voltage line supplied with the negative word line voltage via transistor 721 and/or transistor 728. Similarly, respective ones of the number of sub-word line drivers 790 are indicated as off or inactive as controlled by phase signal line PH1 (e.g., at −0.1 volts) and phase signal line PHF1 (e.g., at 3 volts). Respective ones of word lines WL1, WL5, WL9, and WL13 are therefore indicated to have a low voltage (e.g., −0.1 volts). Respective ones of transistors 771, 772, 774, 776, and 778 of the chain of transistors 770 are indicated as driven at a high voltage (e.g., 3 volts) by phase signal line PHF1, and are therefore on for coupling the word lines WL1, WL5, WL9, and WL13 to the voltage line supplied with the negative word line voltage via transistor 771 and/or transistor 778.

FIG. 13B is a schematic diagram of SWD circuitry 1300 of FIG. 13A, indicating signal state changes of the control signals (e.g., via the phase signal lines, in comparison to FIG. 13A) for activation of word line WL0, according to an example operating scenario. In the example operating scenario of FIG. 13B, phase signal line PH0 is set from a low voltage (e.g., −0.1 volts) to a high voltage (e.g., 3 volts), and phase signal line PHF0 is set from a high voltage (e.g., 3 volts) to a low voltage (e.g., −0.1 volts), the number of sub-word line drivers 780 are turned on or active. Main word line MWL0 is set from a low voltage (e.g., −0.1 volts) to a high voltage (e.g., 3 volts), and therefore word line WL0 is set to the high voltage (e.g., 3 volts). Word lines WL4, WL8, and WL12 remain at the low voltage (e.g., −0.1 volts) through main word lines MWL1, MWL2, and MWL3 at the low voltage, respectively. As phase signal line PHF0 is set from the high voltage (e.g., 3 volts) (i.e., where the chain of transistors 720 are “on”) to the low voltage (e.g., −0.1 volts), the chain of transistors 720 are turned off or inactive. The chain of transistors 720 are turned off to decouple word lines WL0, WL4, WL8, and WL12 from the voltage line supplied with the negative word line voltage provided via transistor 721 and/or transistor 728. On the other hand, phase signal line PH1 remains at a low voltage (e.g., −0.1 volts) and phase signal line PHF1 remains at a high voltage (e.g., 3 volts), and therefore the number of sub-word line drivers 790 remain off or inactive. As phase signal line PHF1 remains at a high voltage (e.g., 3 volts), the chain of transistors 770 remain on for continued coupling of word lines WL1, WL5, WL9, and WL13 to the voltage line supplied with the negative word line voltage via transistor 771 and/or transistor 778.

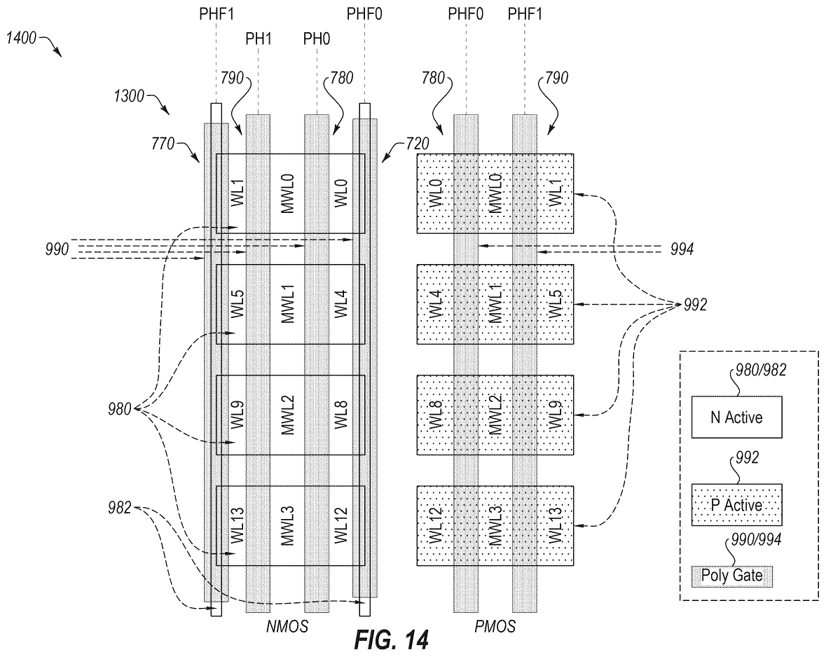

FIG. 14 depicts a layout 1400 of SWD circuitry 1300 of FIGS. 13A and 13B, according to one or more examples. A layout portion of layout 1400 on a left-hand side of FIG. 14 (i.e., the NMOS side) is substantially the same as the layout portion on the left-hand side of layout 900 of FIG. 9, except that in layout 1400 the number of sub-word line drivers 780 and the number of sub-word line drivers 790 are provided in place of the single SWD transistors. A layout portion of layout 1400 on a right-hand side of FIG. 14 (i.e., the PMOS side) depicts the PMOS areas of SWD circuitry 1300 of FIGS. 13A and 13B.

More particularly, the layout portion of SWD circuitry 1300 on the right-hand side of FIG. 14 (i.e., the PMOS side) includes a number of active regions 992 (i.e., P active regions) and a number of gate regions 994. Respective ones of active regions 992 (e.g., four (4) active regions) are formed as horizontal or row-wise regions (with spacings or separations therebetween). Respective ones of gate regions 994 (e.g., four (4) gate regions) are formed as relatively narrow, vertical, or columnar regions (with spacings or separations therebetween).

The gate region associated with phase signal line PHF0 is formed over the number of active regions 992 on middle-left sides of active regions 992, for the formation of the PMOS transistors in the complementary pairs of transistors of the number of sub-word line drivers 780. More particularly, a portion of the gate region associated with phase signal line PHF0 forms a gate of the PMOS transistor (e.g., transistor 713 of FIGS. 13A and 13B) in the complementary pair of transistors of the first sub-word line driver between main word line MWL0 and word line WL0 in a first active region; a portion of the gate region associated with phase signal line PHF0 forms a gate of the PMOS transistor (e.g., transistor 715 of FIGS. 13A and 13B) in the complementary pair of transistors of the second sub-word line driver between main word line MWL1 and word line WL4 in a second active region; a portion of the gate region associated with phase signal line PHF0 forms a gate of the PMOS transistor (e.g., transistor 717 of FIGS. 13A and 13B) in the complementary pair of transistors of the third sub-word line driver between main word line MWL2 and word line WL8 in a third active region; and a portion of the gate region associated with phase signal line PHF0 forms a gate of the PMOS transistor (e.g., transistor 719 of FIGS. 13A and 13B) in the complementary pair of transistors of the fourth sub-word line driver between main word line MWL3 and word line WL12 in a fourth active region.

The gate region associated with phase signal line PHF1 is formed over the number of active regions 992 on middle-right sides of active regions 992, for the formation of the PMOS transistors in the complementary pairs of transistors of the number of sub-word line drivers 790. More particularly, a portion of the gate region associated with phase signal line PHF1 forms a gate of the PMOS transistor (e.g., transistor 763 of FIGS. 13A and 13B) in the complementary pair of transistors of the fifth sub-word line driver between main word line MWL0 and word line WL1 in the first active region; a portion of the gate region associated with phase signal line PHF1 forms a gate of the PMOS transistor (e.g., transistor 765 of FIGS. 13A and 13B) in the complementary pair of transistors of the sixth sub-word line driver between main word line MWL1 and word line WL5 in the second active region; a portion of the gate region associated with phase signal line PHF1 forms a gate of the PMOS transistor (e.g., transistor 767 of FIGS. 13A and 13B) in the complementary pair of transistors of the seventh sub-word line driver between main word line MWL2 and word line WL9 in the third active region; and a portion of the gate region associated with phase signal line PHF1 forms a gate of the PMOS transistor (e.g., transistor 769 of FIGS. 13A and 13B) in the complementary pair of transistors of the eighth sub-word line driver between main word line MWL3 and word line WL13 in the fourth active region.

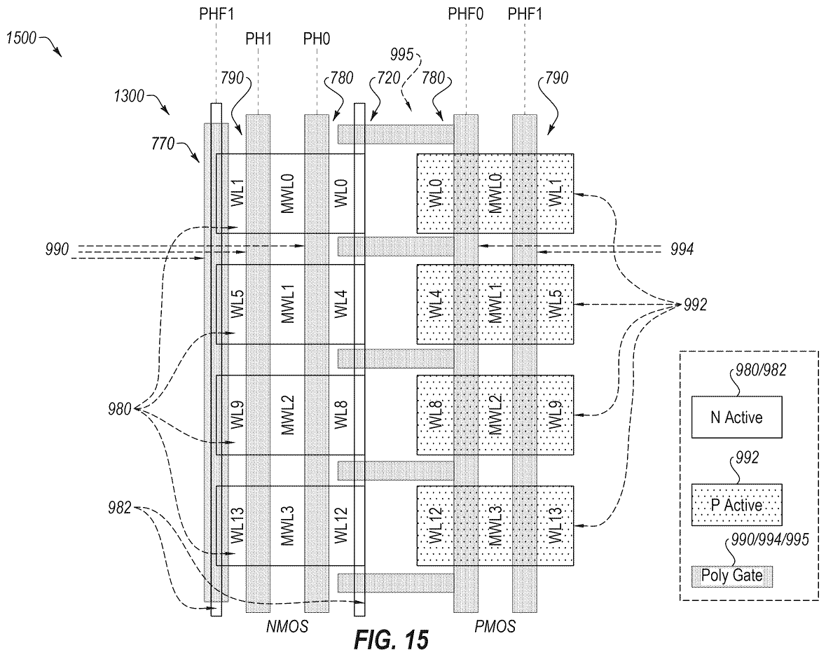

FIG. 15 depicts a layout 1500 of SWD circuitry 1300 of FIGS. 13A and 13B, according to one or more examples. A layout portion of layout 1500 on a left-hand side of FIG. 15 (i.e., the NMOS side) is substantially the same as the layout portion on the left-hand side of layout 1400 of FIG. 14, and a layout portion of layout 1500 on a right-hand side of FIG. 15 (i.e., the PMOS side) is substantially the same as the layout portion on the right-hand side of layout 1400 of FIG. 14. In layout 1500, however, the rightmost gate region of the number of gate regions 990 associated with phase signal line PHF0 (i.e., on the NMOS side) is omitted, and a number of additional gate regions 995 associated with phase signal line PHF0 are provided. Respective ones of additional gate regions 995 (e.g., five (5) additional gate regions from top to bottom) are formed as horizontal or row-wise regions with spacings or separations therebetween. Respective ones of additional gate regions 995 extend from a leftmost edge of the leftmost gate region of the number of gate regions 994 associated with phase signal line PHF0 (i.e., on the PMOS side) towards and over the rightmost additional active region of the number of additional active regions 982. Respective ones of additional gate regions 995 (and/or ends thereof) are formed within respective spacings between and adjacent active regions of the number of active regions 992 (i.e., the P active regions) and within respective spacings between and adjacent active regions of the number of active regions 980 (i.e., the N active regions).

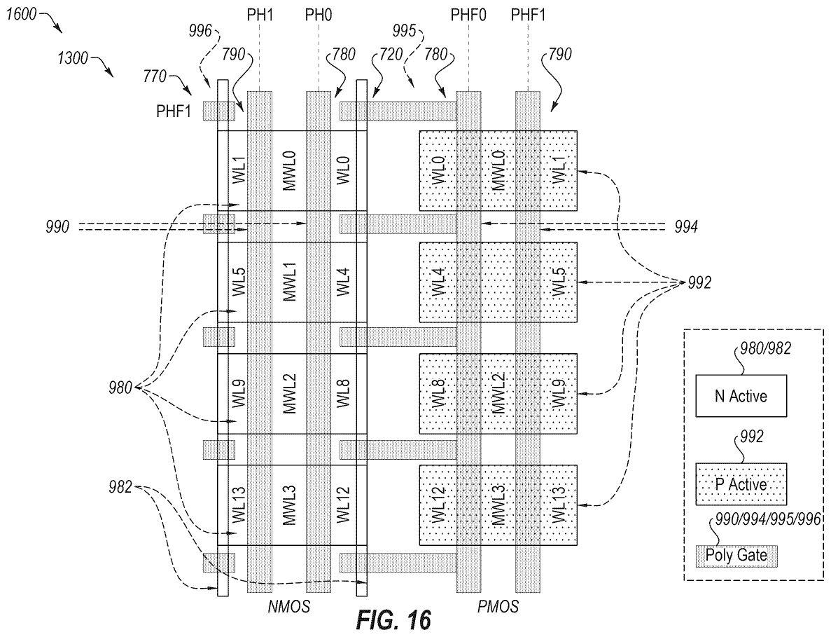

FIG. 16 depicts a layout 1600 of SWD circuitry 1300 of FIGS. 13A and 13B, according to one or more examples. A layout portion of layout 1600 on a left-hand side of FIG. 16 (i.e., the NMOS side) is substantially the same as the layout portion on the left-hand side of layout 1500 of FIG. 15, and a layout portion of layout 1600 on a right-hand side of FIG. 16 (i.e., the PMOS side) is the same as the layout portion on the right-hand side of layout 1500 of FIG. 15. In layout 1600, however, the leftmost gate region of the number of gate regions 990 associated with phase signal line PHF1 (i.e., on the NMOS side) is omitted, and a number of additional gate region portions 996 associated with phase signal line PHF1 are formed. Respective ones of additional gate region portions 996 (e.g., five (5) additional gate region portions from top to bottom) are formed as horizontal or row-wise region portions with spacings or separations therebetween. Respective ones of additional gate region portions 996 are formed over respective regions of the leftmost additional active region of the number of additional active regions 982. Respective ones of additional gate region portions 996 are formed within respective spacings between and adjacent active regions of the number of active regions 980 (i.e., the N active regions).

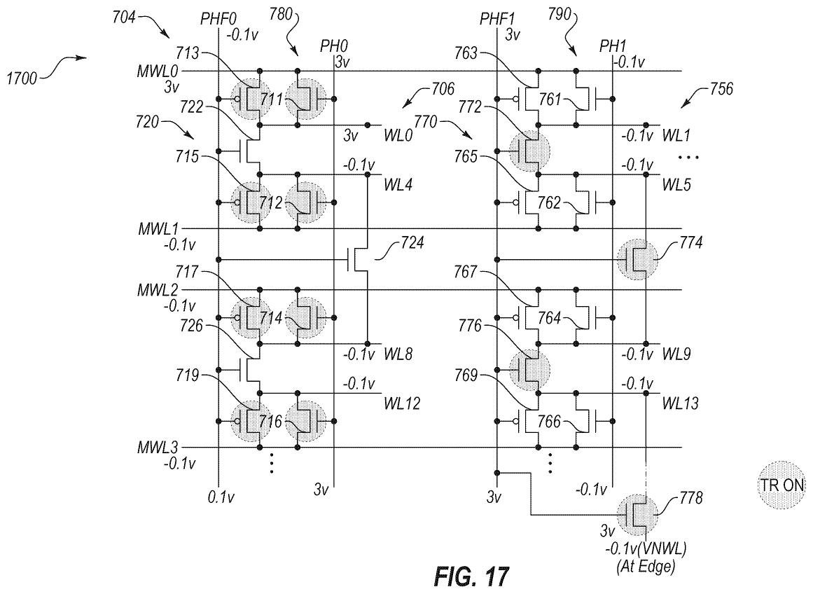

FIG. 17 is a schematic diagram of sub-word line driver (SWD) circuitry 1700 including mux style sub-word line drivers and at least one chain of transistors, according to one or more examples. SWD circuitry 1700 of FIG. 17 is based on, or built upon, SWD circuitry 1300 of FIGS. 13A and 13B, with use of (terminating) transistor 778 in the chain of transistors 770 at the edge (e.g., at the edge only), and/or without use of terminating transistors in the chain of transistors 720 (e.g., transistors 721 and 728 of FIGS. 13A and 13B) and the terminating transistor at the top of the chain of transistors 770 (e.g., transistor 771 of FIGS. 13A and 13B). Phase signal line PHF1 is coupled to respective gates of the respective transistors of the chain of transistors 770, which includes (terminating) transistor 778 coupled to the voltage line supplied with the negative word line voltage at the edge.

In FIG. 17, word line WL0 of the first sub-word line driver of the number of sub-word line drivers 780 is activated according to an example operating scenario, which is similar to the example operating scenario shown and described earlier in relation to FIG. 13B. In the example operating scenario of FIG. 17, phase signal line PH0 is set to a high voltage (e.g., 3 volts) and phase signal line PHF0 is set to a low voltage (e.g., −0.1 volts), and therefore the number of sub-word line drivers 780 are turned on or active. Main word line MWL0 is set to a high voltage (e.g., 3 volts), and therefore word line WL0 is set to the high voltage (e.g., 3 volts). Word lines WL4, WL8, and WL12 remain at the low voltage (e.g., −0.1 volts) through main word lines MWL1, MWL2, and MWL3 at the low voltage, respectively. As phase signal line PHF0 is set to the low voltage (e.g., −0.1 volts), the chain of transistors 720 are turned off or inactive. On the other hand, phase signal line PH1 remains at a low voltage (e.g., −0.1 volts) and phase signal line PHF1 remains at a high voltage (e.g., 3 volts), and therefore the number of sub-word line drivers 790 remain off or inactive. As phase signal line PHF1 remains at a high voltage (e.g., 3 volts), the chain of transistors 770 remain on for continued coupling of word lines WL1, WL5, WL9, and WL13 to the voltage line supplied with the negative word line voltage via transistor 778.

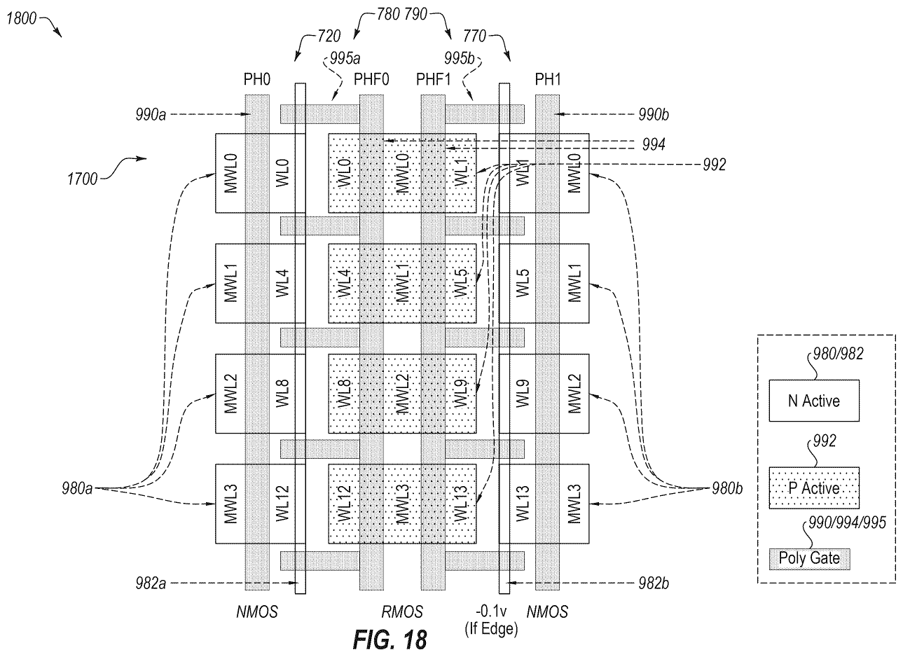

FIG. 18 depicts a layout 1800 of SWD circuitry 1700 of FIG. 17, according to one or more examples. In general, layout 1800 can be considered a “circular shift” of layout 1600 of FIG. 16, to the left, such that the right-hand side of layout 1600 (i.e., the PMOS side) becomes the center of layout 1800 and a left half portion of the left-hand side of layout 1600 (i.e., the left half portion of the NMOS side) becomes the right-hand side of layout 1800.

A layout portion of layout 1800 in the center of the figure (i.e., the PMOS portion) is substantially the same as the layout portion on the right-hand side of layout 1600 of FIG. 16. Portions of the gate region associated with phase signal line PHF0 are formed over respective portions of the number of active regions 992 (i.e., P active regions) on middle-left sides of active regions 992, for the formation of the PMOS transistors in the complementary pairs of transistors of the number of sub-word line drivers 780 as previously described. Portions of the gate region associated with phase signal line PHF1 is formed over respective portions of the number of active regions 992 (i.e., P active regions) on middle-right sides of active regions 992, for the formation of the PMOS transistors in the complementary pairs of transistors of the number of sub-word line drivers 790 as previously described.

On a left-hand side of layout 1800 (i.e., a first NMOS side), a first layout portion of layout 1800 is depicted to include a number of active regions 980a (i.e., N active regions), an additional active region 982a (i.e., an additional N active region), and a gate region 990a. Respective ones of active regions 980a (e.g., four (4) regions) are formed as horizontal or row-wise regions (with spacings or separations therebetween). Gate region 990a associated with phase signal line PH0 is formed as a relatively narrow, vertical, or columnar region. Portions of gate region 990a associated with phase signal line PH0 are formed over respective portions of the number of active regions 980a, in respective center portions of active regions 980, in the formation of the NMOS transistors in the complementary pairs of transistors of the number of sub-word line drivers 780 as previously described.

Additional active region 982a is also formed as a relatively narrow, vertical, or columnar region. Portions of additional active region 982a are formed over respective portions of the number of active regions 980a, over respective right-side edges of active regions 980a. Layout 1800 includes a number of additional gate regions 995a associated with phase signal line PHF0. Respective ones of additional gate regions 995a (e.g., five (5) additional gate regions from top to bottom) are formed as horizontal or row-wise regions with spacings or separations therebetween. Respective ones of additional gate regions 995a extend from a leftmost edge of the leftmost gate region of the number of gate regions 994 associated with phase signal line PHF0 towards and over additional active region 982a. Respective ones of additional gate regions 995a (and/or ends thereof) are formed within respective spacings between and adjacent active regions of the number of active regions 980a. The number of active regions 980a, additional active region 982a, and additional gate regions 995a provide the formation of transistors in the chain of transistors 720 (e.g., in FIG. 17, transistor 722 coupled between word line WL0 and word line WL4, transistor 724 coupled between word line WL4 and word line WL8, and transistor 726 coupled between word line WL8 and word line WL12).

On a right-hand side of layout 1800 (i.e., a second NMOS side), a second layout portion of layout 1800 is depicted to include a number of active regions 980b (i.e., N active regions), an additional active region 982b (i.e., an additional N active region), and a gate region 990b. Respective ones of active regions 980b (e.g., four (4) regions) are formed as horizontal or row-wise regions (with spacings or separations therebetween). Gate region 990b associated with phase signal line PH1 is formed as a relatively narrow, vertical, or columnar region. Portions of gate region 990b associated with phase signal line PH1 are formed over respective portions of the number of active regions 980b, in respective center portions of active regions 980b, in the formation of the NMOS transistors in the complementary pairs of transistors of the number of sub-word line drivers 790 as previously described.

Additional active region 982b is also formed as a relatively narrow, vertical, or columnar region. Portions of additional active region 982b are formed over respective portions of the number of active regions 980b, over respective left-side edges of active regions 980b. Layout 1800 includes a number of additional gate regions 995b associated with phase signal line PHF1. Respective ones of additional gate regions 995b (e.g., five (5) additional gate regions from top to bottom) are formed as horizontal or row-wise regions with spacings or separations therebetween. Respective ones of additional gate regions 995b extend from a rightmost edge of the rightmost gate region of the number of gate regions 994 associated with phase signal line PHF1 towards and over additional active region 982b. Respective ones of additional gate regions 995b (and/or ends thereof) are formed within respective spacings between and adjacent active regions of the number of active regions 980b. The number of active regions 980b, additional active region 982b, and additional gate regions 995b provide the formation of transistors in the chain of transistors 770 (e.g., in FIG. 17, transistor 772 coupled between word line WL1 and word line WL5, transistor 774 coupled between word line WL5 and word line WL9, and transistor 776 coupled between word line WL9 and word line WL13).

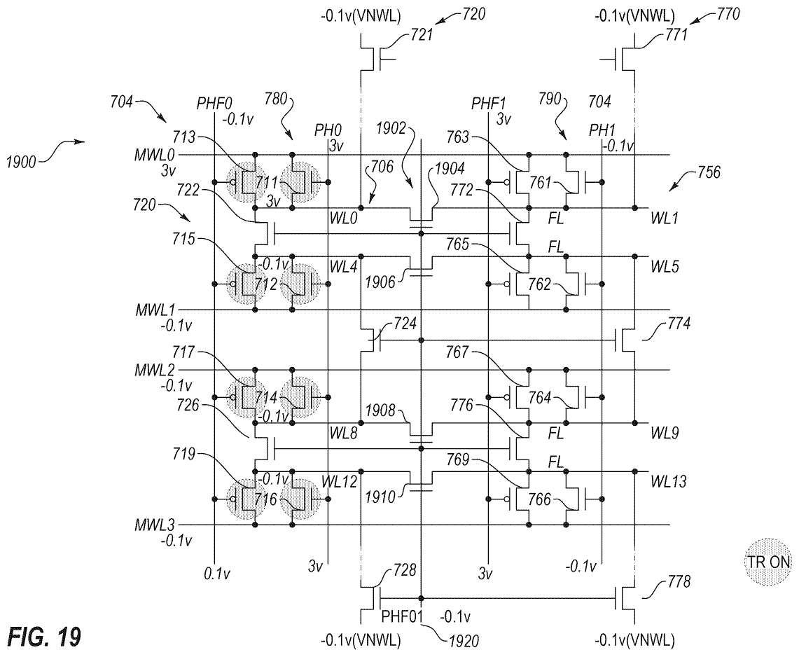

FIG. 19 is a schematic diagram of sub-word line driver (SWD) circuitry 1900 including mux style sub-word line drivers and at least one chain of transistors, according to one or more examples. SWD circuitry 1900 of FIG. 19 is based on, or built upon, SWD circuitry 1300 of FIGS. 13A and 13B, with the additional use of a number of connecting transistors 1902 and a control signal line 1920 (or a phase signal line PHF01).

In FIG. 19, the number of connecting transistors 1902 include connecting transistors 1904, 1906, 1908, and 1910. Respective ones of the number of connecting transistors 1902 are coupled between a respective word line of the number of word lines 706 and a respective word line of the number of word lines 756. In one or more examples of SWD circuitry 1900, connecting transistor 1904 is coupled between the word line WL0 and the word line WL1, connecting transistor 1906 is coupled between the word line WL4 and the word line WL9, connecting transistor 1908 is coupled between the word line WL8 and the word line WL9, and connecting transistor 1910 is coupled between the word line WL12 and the word line WL13.

Control signal line 1920 (or phase signal line PHF01) is coupled to respective gates of the respective transistors of the number of connecting transistors 1902. Control signal line 1920 is further coupled to respective gates of the respective transistors of the chain of transistors 720 (e.g., transistors 721, 722, 724, 726, and 728), and to respective gates of the respective transistors of the chain of transistors 770 (e.g., transistors 771, 772, 774, 776, and 778). Phase signal line PHF0 is no longer coupled to respective gates of the respective transistors of the chain of transistors 720 (i.e., as compared to SWD circuitry 1300 of FIGS. 13A and 13B), and phase signal line PHF1 is no longer coupled to respective gates of the respective transistors of the chain of transistors 770 (i.e., as compared to SWD circuitry 1300 of FIGS. 13A and 13B).

In FIG. 19, word line WL0 of the first sub-word line driver of the number of sub-word line drivers 780 is activated according to an example operating scenario, which is similar to the example operating scenario shown and described earlier in relation to FIG. 13B. In the example operating scenario of FIG. 19, phase signal line PH0 is set to a high voltage (e.g., 3 volts) and phase signal line PHF0 is set to a low voltage (e.g., −0.1 volts), and therefore the number of sub-word line drivers 780 are turned on or active. Main word line MWL0 is set to a high voltage (e.g., 3 volts), and therefore word line WL0 is set to the high voltage (e.g., 3 volts). Word lines WL4, WL8, and WL12 remain at the low voltage (e.g., −0.1 volts) through main word lines MWL1, MWL2, and MWL3 at the low voltage, respectively. On the other hand, phase signal line PH1 is set at a low voltage (e.g., −0.1 volts) and phase signal line PHF1 is set at a high voltage (e.g., 3 volts), and therefore the number of sub-word line drivers 790 remain off or inactive. The word lines WL1, WL5, WL9, and WL13 would be floating (“FL”) as indicated in the figure.

As control signal line 1920 (or phase signal line PHF01) is set at a low voltage (e.g., −0.1 volts), the number of connecting transistors 1902 are off. More particularly, connecting transistor 1904 is off to decouple word line WL0 from word line WL1, connecting transistor 1906 is off to decouple word line WL4 from word line WL5, connecting transistor 1908 is off to decouple word line WL8 from word line WL9, and connecting transistor 1910 is off to decouple word line WL12 from word line WL13. As control signal line 1920 is set at the low voltage, the chain of transistors 720 are also off to decouple word lines WL0, WL4, WL8, and WL12 from the voltage line supplied with the negative word line voltage via transistor 728, and the chain of transistors 770 are also off to decouple word lines WL1, WL5, WL9, and WL13 from the voltage line supplied with the negative word line voltage via transistor 778.

In another operating scenario, control signal line 1920 (or phase signal line PHF01) is to set a high voltage (e.g., 3 volts). When control signal line 1920 is to set the high voltage, the number of connecting transistors 1902 are turned on. More particularly, connecting transistor 1904 is on to couple word line WL0 to word line WL1, connecting transistor 1906 is on to couple word line WL4 to word line WL5, connecting transistor 1908 is on to couple word line WL8 to word line WL9, and connecting transistor 1910 is on to couple word line WL12 to word line WL13. Also when control signal line 1920 (or phase signal line PHF01) is to set the high voltage, the chain of transistors 720 are set or maintained in an on state to couple the number of word lines 706 to the voltage line supplied with the inactive voltage via terminating transistor 721 and/or 728. The high voltage on control signal line 1920 is also to set or maintain the chain of transistors 770 in the on state to couple the number of word lines 756 to the voltage line supplied with the inactive voltage via terminating transistor 771 and/or 778. In one or more examples, control signal line 1920 is to provide the high voltage to set or maintain the transistors of the chains in the on state to maintain floating word lines at the inactive voltage.

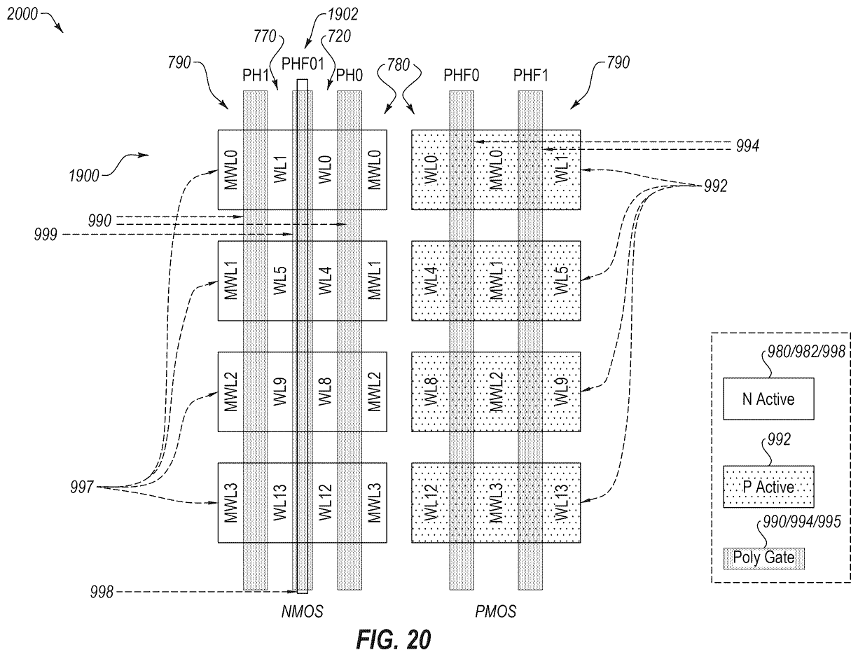

FIG. 20 depicts a layout 2000 of SWD circuitry 1900 of FIG. 19, according to one or more examples. A layout portion of layout 2000 on a right-hand side of FIG. 20 (i.e., the PMOS side) is the same as the layout portion on the right-hand side of layout 1400 of FIG. 14. The gate region associated with phase signal line PHF0 is formed over the number of active regions 992 on middle-left sides of active regions 992, for the formation of the PMOS transistors in the complementary pairs of transistors of the number of sub-word line drivers 780. The gate region associated with phase signal line PHF1 is formed over the number of active regions 992 on middle-right sides of active regions 992, for the formation of the PMOS transistors in the complementary pairs of transistors of the number of sub-word line drivers 790.

A layout portion of layout 2000 on a left-hand side of FIG. 20 (i.e., the NMOS side) includes a number of active regions 997 (e.g., N active regions), an additional active region 998 (e.g., an additional N active region), a number of gate regions 990 and an additional gate region 999. Respective ones of active regions 997 (e.g., four (4) active regions) are formed as horizontal or row-wise regions (with spacings or separations therebetween). Respective ones of gate regions 990 (e.g., two (2) gate regions) are formed as relatively narrow, vertical, or columnar regions (with spacings or separations therebetween). A first gate region of the number of gate regions 990 is associated with phase signal line PH0 and a second gate region of the number of gate regions 990 is associated with phase signal line PH1.

The first gate region of the number of gate regions 990 associated with phase signal line PH0 is formed to overlap the number of active regions 997, on middle-right sides of active regions 997, in the formation of the NMOS transistors of the number of sub-word line drivers 780. More particularly, a portion of the first gate region associated with phase signal line PH0 forms a gate of the NMOS transistor (e.g., transistor 711 of FIG. 19) in the complementary pair of transistors of the first sub-word line driver between main word line MWL0 and word line WL0 in a first active region; a portion of the first gate region associated with phase signal line PH0 forms a gate of the NMOS transistor (e.g., transistor 712 of FIG. 19) in the complementary pair of transistors of the second sub-word line driver between main word line MWL1 and word line WL4 in a second active region; a portion of the first gate region associated with phase signal line PH0 forms a gate of the NMOS transistor (e.g., transistor 714 of FIG. 19) in the complementary pair of transistors of the third sub-word line driver between main word line MWL2 and word line WL8 in a third active region; and a portion of the first gate region associated with phase signal line PH0 forms a gate of the NMOS transistor (e.g., transistor 716 of FIG. 19) in the complementary pair of transistors of the fourth sub-word line driver between main word line MWL3 and word line WL12 in a fourth active region.

The second gate region of the number of gate regions 990 associated with phase signal line PH1 is formed to overlap the number of active regions 997, on middle-left sides of active regions 997, in the formation of the NMOS transistors of the number of sub-word line drivers 790. More particularly, a portion of the second gate region associated with phase signal line PH1 forms a gate of the NMOS transistor (e.g., transistor 761 of FIG. 19) in the complementary pair of transistors of the fifth sub-word line driver between main word line MWL0 and word line WL1 in the first active region; a portion of the second gate region associated with phase signal line PH1 forms a gate of the NMOS transistor (e.g., transistor 762 of FIG. 19) in the complementary pair of transistors of the sixth sub-word line driver between main word line MWL1 and word line WL5 in the second active region; a portion of the second gate region associated with phase signal line PH1 forms a gate of the NMOS transistor (e.g., transistor 764 of FIG. 19) in the complementary pair of transistors of the seventh sub-word line driver between main word line MWL2 and word line WL9 in the third active region; and a portion of the second gate region associated with phase signal line PH1 forms a gate of the NMOS transistor (e.g., transistor 766 of FIG. 19) in the complementary pair of transistors of the eighth sub-word line driver between main word line MWL3 and word line WL13 in the fourth active region.

Additional active region 998 is formed as a relatively narrow, vertical, or columnar region in between the gate regions 990 associated with phase signal lines PH0 and PH1 portions of which are formed over respective center portions of active regions 997. Additional gate region 999 associated with phase signal line PHF01 (i.e., control signal line 1920 of FIG. 19) is also a relatively narrow, vertical, or columnar region, a bit wider and shorter in length than additional active region 998 but otherwise formed generally coextensive with additional gate region 999. The formation of additional gate region 999 associated with PHF01 over additional active region 998 and the number of active regions 997 provides the formation of the number of connecting transistors 1902 (e.g., in FIG. 19, transistor 1904 coupled between word line WL0 and word line WL1, transistor 1906 coupled between word line WL4 and word line WL5, transistor 1908 coupled between word line WL8 and word line WL9, and transistor 1910 coupled between word line WL12 and word line WL13). On a right hand side of additional gate region 999 associated with PHF01, the n-type transistors of the chain of transistors 720 are formed (e.g., transistor 722 coupled between word line WL0 and word line WL4, transistor 724 coupled between word line WL4 and word line WL8, and transistor 726 coupled between word line WL8 and word line WL12). On a left hand side of additional gate region 999 associated with PHF01, the n-type transistors of the chain of transistors 770 are formed (e.g., transistor 772 coupled between word line WL1 and word line WL5, transistor 774 coupled between word line WL5 and word line WL9, and transistor 776 coupled between word line WL9 and word line WL13).

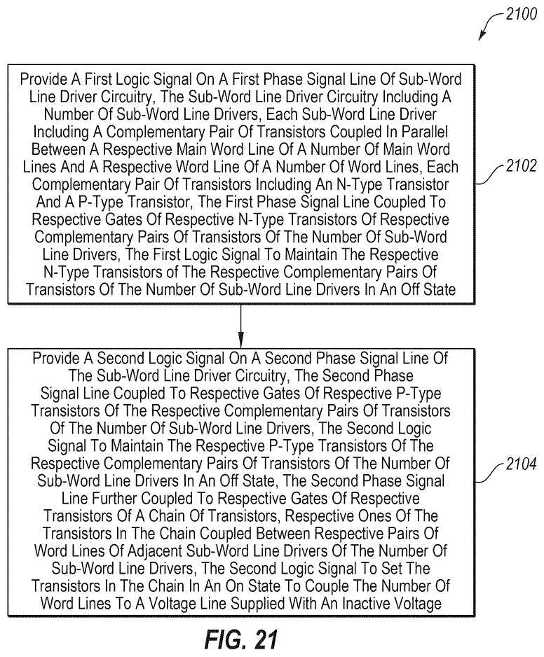

FIG. 21 is a flowchart of a method 2100 of removing floating word line states of word lines of SWD circuitry according to one or more examples. Method 2100 may be associated with use of SWD circuitry 1300 of FIGS. 13A and 13B, or SWD circuitry 1700 of FIG. 17, according to one or more examples.

Beginning at an act 2102, a first logic signal is provided on a first phase signal line of sub-word line driver circuitry. The sub-word line driver circuitry includes a number of sub-word line drivers. Each sub-word line driver includes a complementary pair of transistors coupled in parallel between a respective main word line of a number of main word lines and a respective word line of a number of word lines. Each complementary pair of transistors includes an N-type transistor and a P-type transistor. The first phase signal line is coupled to respective gates of respective N-type transistors of respective complementary pairs of transistors of the number of sub-word line drivers. The first logic signal is to maintain the respective N-type transistors of the respective complementary pairs of transistors of the number of sub-word line drivers in an off state.

At an act 2104, a second logic signal is provided on a second phase signal line of the sub-word line driver circuitry. In one or more examples, the second logic signal is provided on the second phase signal line while the first logic signal is provided on the first phase signal line. The second phase signal line is coupled to respective gates of respective P-type transistors of the respective complementary pairs of transistors of the number of sub-word line drivers. The second logic signal is to maintain the respective P-type transistors of the respective complementary pairs of transistors of the number of sub-word line drivers in an off state. The second phase signal line is further coupled to respective gates of respective transistors of a chain of transistors. Respective ones of the transistors of the chain is coupled between respective pairs of word lines of adjacent sub-word line drivers of the number of sub-word line drivers. The second logic signal is to set the transistors of the chain in an on state to couple the number of word lines to a voltage line supplied with an inactive voltage.

In one or more examples of method 2100, at the act 2104, the second logic signal on the second phase signal line is to set or maintain the transistors of the chain in the on state to couple the number of word lines to the voltage line supplied with the inactive voltage via a terminating transistor coupled between at least one of the number of word lines and the voltage line. In one or more examples, the second logic signal is provided on the second phase signal line is to set or maintain the transistors of the chain in the on state to maintain floating word lines at the inactive voltage via the terminating transistor.

In one or more examples, method 2100 further includes providing the second logic signal on the first phase signal line of the sub-word line driver circuitry. The second logic signal is provided on the first phase signal line to set the respective N-type transistors of the respective complementary pairs of transistors of the number of sub-word line drivers in an on state. Method 2100 further includes providing the first logic signal on the second phase signal line of the sub-word line driver circuitry. In one or more examples, the first logic signal is provided on the second phase signal line while the second logic signal is provided on the first phase signal line. In one or more examples, the first logic signal is provided on the second phase signal line to set the respective P-type transistors of the respective complementary pairs of transistors of the number of sub-word line drivers in an on state. In one or more examples, the first logic signal is provided on the second phase signal line to set the transistors of the chain in an off state to decouple the number of word lines from the voltage line supplied with the inactive voltage provided via the terminating transistor.

In one or more examples of the disclosure, area efficiency (AE) of a memory array may be improved through use of the chain structures of the sub-word line driver circuitry described herein. In one or more examples, transistor reliability may be improved by rotation of the transistor gate(s) of the sub-word line drivers. In one or more examples, termination of the inactive voltage (e.g., VNWL) for the chain structures may be provided at the top and bottom edges only (e.g., or alternatively, at a bottom, side edge only). As conventional VNWL termination is provided at each individual sub-word line driver, the inventive arrangement saves VNWL active and contact layout at each individual sub-word line driver. In one or more examples, the channel length of the transistor is not limited by word line pitch. In one or more examples, the transistor's channel length can be adjusted according to reliability stress.

A memory device is also disclosed herein. According to one or more examples, the memory device may include one or more memory cell arrays, such as memory array 250 (see FIG. 2). The one or more memory cell arrays may include a number of memory cells.

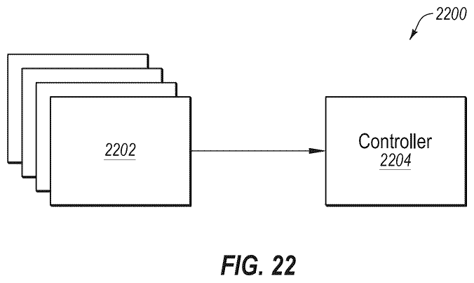

FIG. 22 is a simplified block diagram of a memory device 2200 implemented according to one or more examples described herein. Memory device 2200, which may include, for example, a semiconductor device, includes a memory array 2202 and a controller 2204. Memory array 2202, which may include a number of memory banks, may include a number of memory cells. Controller 2204 may be operatively coupled with memory array 2202 so as to read, write, or refresh any or all memory cells within memory array 2202. Controller 2204 may be adapted to carry out one or more examples disclosed herein. For example, controller 2204 may include at least a portion of SWD circuitry 700 of FIGS. 7A and 7B, arranged with or without layout 900 of FIG. 9.

A system is also disclosed herein. According to one or more examples, the system may include a memory device including a number of memory banks, each memory bank having an array of memory cells. Each memory cell may include an access transistor and a storage element operably coupled with the access transistor.

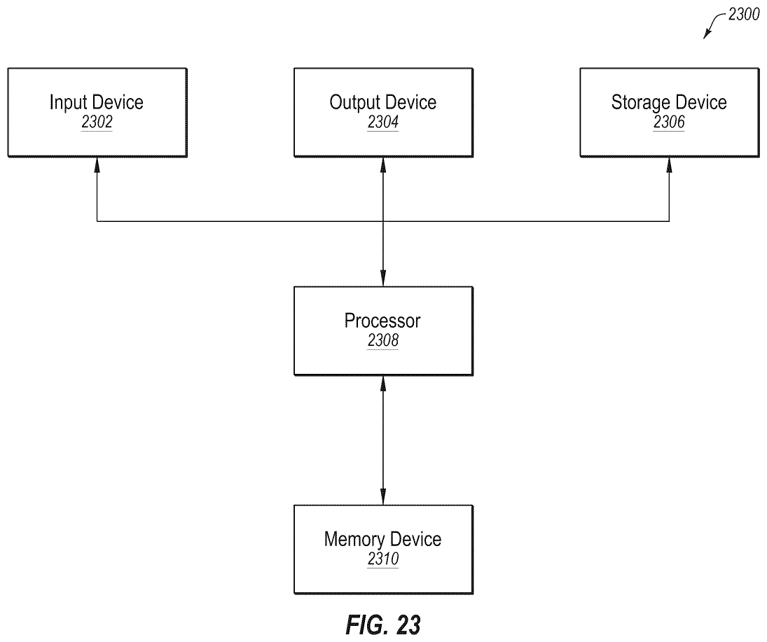

FIG. 23 is a simplified block diagram of an electronic system 2300 implemented according to one or more examples described herein. Electronic system 2300 includes at least one input device 2302, which may include, for example, a keyboard, a mouse, or a touch screen. Electronic system 2300 further includes at least one output device 2304, such as a monitor, a touch screen, or a speaker. Input device 2302 and output device 2304 are not necessarily separable from one another. Electronic system 2300 further includes a storage device 2306. Input device 2302, output device 2304, and storage device 2306 may be coupled to a processor 2308. Electronic system 2300 further includes a memory device 2310 coupled to processor 2308. Memory device 2310, which may include memory device 200 of FIG. 2, may include an array of memory cells. Electronic system 2300 may include, for example, a computing, processing, industrial, or consumer product. For example, without limitation, electronic system 2300 may include a personal computer or computer hardware component, a server or other networking hardware component, a database engine, an intrusion prevention system, a handheld device, a tablet computer, an electronic notebook, a camera, a phone, a music player, a wireless device, a display, a chip set, a game, a vehicle, or other known systems.

Accordingly, in various examples, a device is disclosed. The device comprises a number of sub-word line drivers and a chain of transistors. Each sub-word line driver includes a complementary pair of transistors coupled in parallel between a respective main word line of a number of main word lines and a respective word line of a number of word lines. Each complementary pair of transistors includes an N-type transistor and a P-type transistor. A first phase signal line is coupled to respective gates of respective N-type transistors of respective complementary pairs of transistors of the number of sub-word line drivers. A second phase signal line is coupled to respective gates of respective P-type transistors of the respective complementary pairs of transistors of the number of sub-word line drivers. Respective transistors of the chain of transistors are coupled between respective pairs of word lines of adjacent sub-word line drivers of the number of sub-word line drivers. The chain of transistors includes a terminating transistor coupled between a first end word line of the number of word lines and a voltage line supplied with an inactive voltage.

In further examples, another device is disclosed. The device comprises a number of word lines, a number of main word lines, a first phase signal line, a second phase signal line, and a chain of transistors. The number of word lines includes at least a first word line, a second word line, a third word line, and a fourth word line. Each sub-word line driver includes a complementary pair of transistors coupled in parallel between a respective main word line of the number of main word lines and a respective word line of the number of word lines. Each complementary pair of transistors includes an N-type transistor and a P-type transistor. The first phase signal line is coupled to respective gates of respective N-type transistors of respective complementary pairs of transistors of the number of sub-word line drivers. The second phase signal line is coupled to respective gates of respective P-type transistors of the respective complementary pairs of transistors of the number of sub-word line drivers. The chain of transistors includes a first transistor coupled between the first word line and a voltage line supplied with an inactive voltage, a second transistor coupled between the first word line and the second word line, a third transistor coupled between the second word line and the third word line, and a fourth transistor coupled between the third word line and the fourth word line. In one or more examples, the second phase signal line is coupled to respective gates of the respective transistors of the chain of transistors.

In yet further examples, a system is disclosed. The system comprises at least one input device, at least one output device, at least one processor device operably coupled to the input device and the output device, and at least one memory device operably coupled to the at least one processor device. The at least one memory device comprises a number of sub-word line drivers and a chain of transistors. Each sub-word line driver includes a complementary pair of transistors coupled in parallel between a respective main word line of a number of main word lines and a respective word line of a number of word lines. Each complementary pair of transistors includes an N-type transistor and a P-type transistor. A first phase signal line is coupled to respective gates of respective N-type transistors of respective complementary pairs of transistors of the number of sub-word line drivers. A second phase signal line is coupled to respective gates of respective P-type transistors of the respective complementary pairs of transistors of the number of sub-word line drivers. Respective transistors of the chain of transistors are coupled between respective pairs of word lines of adjacent sub-word line drivers of the number of sub-word line drivers. The chain of transistors includes a terminating transistor coupled between a first end word line of the number of word lines and a voltage line supplied with an inactive voltage.

In yet other examples, a further device is disclosed. The further device comprises a number of sub-word line drivers and a chain of transistors. Each sub-word line driver includes a complementary pair of transistors coupled in parallel between a respective main word line of a number of main word lines and a respective word line of a number of word lines. Each complementary pair of transistors includes an N-type transistor and a P-type transistor. A first phase signal line is coupled to respective gates of respective N-type transistors of respective complementary pairs of transistors of the number of sub-word line drivers. A second phase signal line is coupled to respective gates of respective P-type transistors of the respective complementary pairs of transistors of the number of sub-word line drivers. Respective transistors of the chain of transistors are coupled between respective pairs of word lines of adjacent sub-word line drivers of the number of sub-word line drivers. The chain of transistors includes a terminating transistor coupled between a first end word line of the number of word lines and a voltage line supplied with an inactive voltage. A control signal line is coupled to respective gates of the respective transistors of the chain of transistors.

In one or more examples of the further device, the first phase signal line is to provide a first logic signal to set or maintain the respective N-type transistors of the respective complementary pairs of transistors of the number of sub-word line drivers in an off state; the second phase signal line is to provide a second logic signal to set or maintain the respective P-type transistors of the respective complementary pairs of transistors of the number of sub-word line drivers in an off state, the first logic signal and the second logic signal comprising complementary signals; and the control signal line is to provide the second logic signal to set or maintain the transistors of the chain in an on state to couple the number of word lines to the voltage line supplied with the inactive voltage via the terminating transistor.

In one or more examples of the further device, the control signal line is to provide the second logic signal to set or maintain the transistors of the chain in the on state to maintain floating word lines at the inactive voltage via the terminating transistor, the respective transistors of the chain of transistors comprising n-type transistors.

In one or more examples of the further device, the first phase signal line is to provide the second logic signal to set or maintain the respective N-type transistors of the respective complementary pairs of transistors of the number of sub-word line drivers in an on state; the second phase signal line is to provide the first logic signal to set or maintain the respective P-type transistors of the respective complementary pairs of transistors of the number of sub-word line drivers in an on state; and the control signal line is to provide the first logic signal to set or maintain the transistors of the chain in an off state to decouple the number of word lines from the voltage line supplied with the inactive voltage provided via the terminating transistor.

In one or more examples of the further device, the number of sub-word line drivers comprises a number of first sub-word line drivers, the number of word lines comprises a number of first word lines, the chain of transistors comprises a first chain of transistors, the terminating transistor comprises a first terminating transistor, and the voltage line comprises a first voltage line; the further device comprises: a number of second sub-word line drivers, each second sub-word line driver including a complementary pair of transistors coupled in parallel between a respective main word line of the number of main word lines and a respective second word line of a number of second word lines, each complementary pair of transistors of each second sub-word line driver including an N-type transistor and a P-type transistor; a third phase signal line coupled to respective gates of respective N-type transistors of respective complementary pairs of transistors of the number of second sub-word line drivers; a fourth phase signal line coupled to respective gates of respective P-type transistors of the respective complementary pairs of transistors of the number of second sub-word line drivers; a second chain of transistors, respective transistors in the second chain of transistors coupled between respective pairs of second word lines of adjacent second sub-word line drivers of the number of second sub-word line drivers, the second chain of transistors including a second terminating transistor coupled between a first end word line of the number of second word lines and a second voltage line supplied with the inactive voltage; and the control signal line coupled to respective gates of the respective transistors of the second chain of transistors.

In one or more examples of the further device, the further device comprises a number of connecting transistors, each connecting transistor of the number of connecting transistors coupled between a respective first word line of the number of word lines and a respective second word line of the number of second word lines, the control signal line coupled to respective gates of the respective transistors of the number of connecting transistors.

In yet further examples, a method is disclosed. The method comprises providing a first logic signal on a first phase signal line of sub-word line driver circuitry. The sub-word line driver circuitry includes a number of sub-word line drivers. Each sub-word line driver includes a complementary pair of transistors coupled in parallel between a respective main word line of a number of main word lines and a respective word line of a number of word lines. Each complementary pair of transistors includes an N-type transistor and a P-type transistor. The first phase signal line is coupled to respective gates of respective N-type transistors of respective complementary pairs of transistors of the number of sub-word line drivers. The first logic signal is to maintain the respective N-type transistors of the respective complementary pairs of transistors of the number of sub-word line drivers in an off state. The method further comprises providing a second logic signal on a second phase signal line of the sub-word line driver circuitry. The second phase signal line is coupled to respective gates of respective P-type transistors of the respective complementary pairs of transistors of the number of sub-word line drivers. The second logic signal is to maintain the respective P-type transistors of the respective complementary pairs of transistors of the number of sub-word line drivers in an off state. The second phase signal line is further coupled to respective gates of respective transistors of a chain of transistors. Respective ones of the transistors of the chain are coupled between respective pairs of word lines of adjacent sub-word line driver transistors of the number of sub-word line drivers. The second logic signal is to set the transistors of the chain in an on state to couple the number of word lines to a voltage line supplied with an inactive voltage.

In one or more examples of the method, providing the second logic signal on the second phase signal line is to set or maintain the transistors of the chain in the on state to couple the number of word lines to the voltage line supplied with the inactive voltage via a terminating transistor coupled between at least one of the number of word lines and the voltage line.

In one or more examples of the method, providing the second logic signal on the second phase signal line is to set or maintain the transistors of the chain in the on state to maintain floating word lines at the inactive voltage via the terminating transistor.

In one or more examples of the method, the method comprises providing the second logic signal on the first phase signal line of the sub-word line driver circuitry, the second logic signal on the first phase signal line to set the respective N-type transistors of the respective complementary pairs of transistors of the number of sub-word line drivers in an on state; and providing the first logic signal on the second phase signal line of the sub-word line driver circuitry, the first logic signal on the second phase signal line to set the respective P-type transistors of the respective complementary pairs of transistors of the number of sub-word line drivers in an on state, the first logic signal on the second phase signal line to set the transistors of the chain in an off state to decouple the number of word lines from the voltage line supplied with the inactive voltage provided via the terminating transistor.

As used herein, the terms “memory device” and “memory system” refer to devices and systems configured to temporarily and/or permanently store information related to various electronic devices. Accordingly, the term “memory device” may refer to a single memory die and/or to a memory package containing one or more memory dies. Similarly, the term “memory system” may refer to a system including one or more memory dies (e.g., a memory package) and/or to a system (e.g., a dual in-line memory module (DIMM)) including one or more memory packages.

In accordance with common practice, the various features illustrated in the drawings may not be drawn to scale. The illustrations presented in the present disclosure are not meant to be actual views of any particular apparatus (e.g., device, system, etc.) or method, but are merely idealized representations that are employed to describe various embodiments of the disclosure. Accordingly, the dimensions of the various features may be arbitrarily expanded or reduced for clarity. In addition, some of the drawings may be simplified for clarity. Thus, the drawings may not depict all of the components of a given apparatus (e.g., device) or all operations of a particular method.

As used herein, the term “device” or “memory device” may include a device with memory, but is not limited to a device with only memory. For example, a device or a memory device may include memory, a processor, and/or other components or functions. For example, a device or memory device may include a system on a chip (SOC).

Terms used herein and especially in the appended claims (e.g., bodies of the appended claims) are generally intended as “open” terms (e.g., the term “including” should be interpreted as “including, but not limited to,” the term “having” should be interpreted as “having at least,” the term “includes” should be interpreted as “includes, but is not limited to,” etc.).

Additionally, if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations. As used herein, “and/or” includes any and all combinations of one or more of the associated listed items.

In addition, even if a specific number of an introduced claim recitation is explicitly recited, it is understood that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.,” or “one or more of A, B, and C, etc.,” is used, in general such a construction is intended to include A alone, B alone, C alone, A and B together, A and C together, B and C together, or A, B, and C together, etc. For example, the use of the term “and/or” is intended to be construed in this manner.

Further, any disjunctive word or phrase presenting two or more alternative terms, whether in the description, claims, or drawings, should be understood to contemplate the possibilities of including one of the terms, either of the terms, or both terms. For example, the phrase “A or B” should be understood to include the possibilities of “A” or “B” or “A and B.”

Additionally, the use of the terms “first,” “second,” “third,” etc., are not necessarily used herein to connote a specific order or number of elements. Generally, the terms “first,” “second,” “third,” etc., are used to distinguish between different elements as generic identifiers. Absence a showing that the terms “first,” “second,” “third,” etc., connote a specific order, these terms should not be understood to connote a specific order. Furthermore, absence a showing that the terms “first,” “second,” “third,” etc., connote a specific number of elements, these terms should not be understood to connote a specific number of elements.

As used herein, the term “substantially” in reference to a given parameter, property, or condition means and includes to a degree that one of ordinary skill in the art would understand that the given parameter, property, or condition is met with a small degree of variance, such as, for example, within acceptable manufacturing tolerances. By way of example, depending on the particular parameter, property, or condition that is substantially met, the parameter, property, or condition may be at least 90% met, at least 95% met, or even at least 99% met.

The embodiments of the disclosure described above and illustrated in the accompanying drawings do not limit the scope of the disclosure, which is encompassed by the scope of the appended claims and their legal equivalents. Any equivalent embodiments are within the scope of this disclosure. Indeed, various modifications of the disclosure, in addition to those shown and described herein, such as alternative useful combinations of the elements described, will become apparent to those skilled in the art from the description. Such modifications and embodiments also fall within the scope of the appended claims and equivalents.

What is claimed is:

1. A device comprising:
a number of sub-word line drivers, each sub-word line driver including a complementary pair of transistors coupled in parallel between a respective main word line of a number of main word lines and a respective word line of a number of word lines, each complementary pair of transistors including an N-type transistor and a P-type transistor;
a first phase signal line, the first phase signal line coupled to respective gates of respective N-type transistors of respective complementary pairs of transistors of the number of sub-word line drivers;
a second phase signal line, the second phase signal line coupled to respective gates of respective P-type transistors of the respective complementary pairs of transistors of the number of sub-word line drivers; and
a chain of transistors, respective transistors of the chain of transistors coupled between respective pairs of word lines of adjacent sub-word line drivers of the number of sub-word line drivers, the chain of transistors including a terminating transistor coupled between a first end word line of the number of word lines and a voltage line supplied with an inactive voltage.

2. The device of claim 1, wherein the second phase signal line is coupled to respective gates of the respective transistors of the chain of transistors.

3. The device of claim 2, wherein:
the first phase signal line is to provide a first logic signal to set or maintain the respective N-type transistors of the respective complementary pairs of transistors of the number of sub-word line drivers in an off state;
the second phase signal line is to provide a second logic signal to set or maintain the respective P-type transistors of the respective complementary pairs of transistors of the number of sub-word line drivers in an off state, the first logic signal and the second logic signal comprising complementary signals; and
the second phase signal line is to provide the second logic signal to set or maintain the transistors of the chain in an on state to couple the number of word lines to the voltage line supplied with the inactive voltage via the terminating transistor.

4. The device of claim 3, wherein:
the second phase signal line is to provide the second logic signal to set or maintain the transistors of the chain in the on state to maintain floating word lines at the inactive voltage via the terminating transistor.

5. The device of claim 3, wherein:
the first phase signal line is to provide the second logic signal to set or maintain the respective N-type transistors of the respective complementary pairs of transistors of the number of sub-word line drivers in an on state;
the second phase signal line is to provide the first logic signal to set or maintain the respective P-type transistors of the respective complementary pairs of transistors of the number of sub-word line drivers in an on state; and
the second phase signal line is to provide the first logic signal to set or maintain the transistors of the chain in an off state to decouple the number of word lines from the voltage line supplied with the inactive voltage provided via the terminating transistor.

6. The device of claim 5, wherein:
a respective sub-word line driver of the number of sub-word line drivers is to couple a respective word line to a respective main word line in response to the first phase signal line providing the second logic signal and the first phase signal line providing the first logic signal when the respective main word line is set to a high state.

7. The device of claim 1, wherein the respective transistors of the chain of transistors comprise n-type transistors.

8. The device of claim 1, wherein:
the chain of transistors include another terminating transistor coupled between a second end word line of the number of word lines and another voltage line supplied with the inactive voltage, the inactive voltage comprising a negative word line voltage.

9. The device of claim 1, comprising:
a control signal line coupled to respective gates of the respective transistors of the chain of transistors, the control signal line to provide a second logic signal to set or maintain the transistors of the chain in an on state to couple the number of word lines to the voltage line supplied with the inactive voltage via the terminating transistor.

10. The device of claim 1, wherein the number of sub-word line drivers comprises a number of first sub-word line drivers, the number of word lines comprises a number of first word lines, the chain of transistors comprises a first chain of transistors, the terminating transistor comprises a first terminating transistor, and the voltage line comprises a first voltage line, the device comprising:
a number of second sub-word line drivers, each second sub-word line driver including a complementary pair of transistors coupled in parallel between a respective main word line of the number of main word lines and a respective second word line of a number of second word lines, each complementary pair of transistors of each second sub-word line driver including an N-type transistor and a P-type transistor;
a third phase signal line coupled to respective gates of respective N-type transistors of respective complementary pairs of transistors of the number of second sub-word line drivers;
a fourth phase signal line coupled to respective gates of respective P-type transistors of the respective complementary pairs of transistors of the number of second sub-word line drivers; and
a second chain of transistors, respective transistors in the second chain of transistors coupled between respective pairs of second word lines of adjacent second sub-word line drivers of the number of second sub-word line drivers, the second chain of transistors including a second terminating transistor coupled between a first end word line of the number of second word lines and a second voltage line supplied with the inactive voltage, the fourth phase signal line coupled to respective gates of the respective transistors in the second chain of transistors.

11. The device of claim 10, wherein:
the third phase signal line is to provide a first logic signal to set or maintain the respective N-type transistors of the respective complementary pairs of transistors of the number of second sub-word line drivers in an off state;
the fourth phase signal line is to provide a second logic signal to set or maintain the respective P-type transistors of the respective complementary pairs of transistors of the number of second sub-word line drivers in an off state; and
the fourth phase signal line is to provide the second logic signal to set or maintain the transistors of the chain in an on state to couple the number of word lines to the second voltage line supplied with the inactive voltage via the second terminating transistor.

12. The device of claim 10, wherein:
the third phase signal line is to provide a second logic signal to set or maintain the respective N-type transistors of the respective complementary pairs of transistors of the number of second sub-word line drivers in an on state;
the fourth phase signal line is to provide a first logic signal to set or maintain the respective P-type transistors of the respective complementary pairs of transistors of the number of second sub-word line drivers in an on state; and
the fourth phase signal line is to provide the first logic signal to set or maintain the transistors in the second chain in an off state to decouple the number of second word lines from the second voltage line supplied with the inactive voltage provided via the second terminating transistor.

13. A device comprising:
a number of word lines, the number of word lines including at least a first word line, a second word line, a third word line, and a fourth word line;
a number of main word lines;
a number of sub-word line drivers, each sub-word line driver including a complementary pair of transistors coupled in parallel between a respective main word line of the number of main word lines and a respective word line of the number of word lines, each complementary pair of transistors including an N-type transistor and a P-type transistor;
a first phase signal line, the first phase signal line coupled to respective gates of respective N-type transistors of respective complementary pairs of transistors of the number of sub-word line drivers;
a second phase signal line, the second phase signal line coupled to respective gates of respective P-type transistors of the respective complementary pairs of transistors of the number of sub-word line drivers; and
a chain of transistors including:
a first transistor coupled between the first word line and a voltage line supplied with an inactive voltage;
a second transistor coupled between the first word line and the second word line;
a third transistor coupled between the second word line and the third word line; and
a fourth transistor coupled between the third word line and the fourth word line.

14. The device of claim 13, wherein the second phase signal line is coupled to respective gates of respective transistors of the chain of transistors.

15. The device of claim 14, wherein the respective transistors of the chain of transistors comprise n-type transistors.

16. The device of claim 14, wherein the number of sub-word line drivers includes:
a first sub-word line driver to decouple the first word line from a first main word line responsive to a first logic signal on the first phase signal line and a second logic signal on the second phase signal line, the first sub-word line driver to couple the first word line to the first main word line responsive to the second logic signal on the first phase signal line and the first logic signal on the second phase signal line;
a second sub-word line driver to decouple the second word line from a second main word line responsive to the first logic signal on the first phase signal line and the second logic signal on the second phase signal line, the second sub-word line driver to couple the second word line to the second main word line responsive to the second logic signal on the first phase signal line and the first logic signal on the second phase signal line;
a third sub-word line driver to decouple the third word line from a third main word line responsive to the first logic signal on the first phase signal line and the second logic signal on the second phase signal line, the second sub-word line driver to couple the third word line to the third main word line responsive to the second logic signal on the first phase signal line and the first logic signal on the second phase signal line; and
a fourth sub-word line driver to decouple the fourth word line from a fourth main word line responsive to the first logic signal on the first phase signal line and the second logic signal on the second phase signal line, the second sub-word line driver to couple the fourth word line to the fourth main word line responsive to the second logic signal on the first phase signal line and the first logic signal on the second phase signal line;
wherein the first logic signal on the second phase signal line is to set the transistors of the chain in an on state to couple the number of word lines to the voltage line supplied with the inactive voltage; and
wherein the second logic signal on the second phase signal line is to set the transistors of the chain in an off state to decouple the number of word lines from the voltage line supplied with the inactive voltage.

17. A system comprising:
at least one input device;
at least one output device;
at least one processor device operably coupled to the input device and the output device; and
at least one memory device operably coupled to the at least one processor device and including:
a number of sub-word line drivers, each sub-word line driver including a complementary pair of transistors coupled in parallel between a respective main word line of a number of main word lines and a respective word line of a number of word lines, each complementary pair of transistors including an N-type transistor and a P-type transistor;
a first phase signal line, the first phase signal line coupled to respective gates of respective N-type transistors of respective complementary pairs of transistors of the number of sub-word line drivers;
a second phase signal line, the second phase signal line coupled to respective gates of respective P-type transistors of the respective complementary pairs of transistors of the number of sub-word line drivers; and
a chain of transistors, respective transistors of the chain of transistors coupled between respective pairs of word lines of adjacent sub-word line drivers of the number of sub-word line drivers, the chain of transistors including a terminating transistor coupled between a first end word line of the number of word lines and a voltage line supplied with an inactive voltage.

18. The system of claim 17, wherein the second phase signal line is coupled to respective gates of the respective transistors of the chain of transistors.

19. The system of claim 18, wherein:
the first phase signal line is to provide a first logic signal to set or maintain the respective N-type transistors of the respective complementary pairs of transistors of the number of sub-word line drivers in an off state;
the second phase signal line is to provide a second logic signal to set or maintain the respective P-type transistors of the respective complementary pairs of transistors of the number of sub-word line drivers in an off state, the first logic signal and the second logic signal comprising complementary signals; and
the second phase signal line is to provide the second logic signal to set or maintain the transistors of the chain in an on state to couple the number of word lines to the voltage line supplied with the inactive voltage via the terminating transistor, to maintain floating word lines at the inactive voltage via the terminating transistor.

20. The system of claim 17, comprising:
a control signal line coupled to respective gates of the respective transistors of the chain of transistors, the control signal line to provide a second logic signal to set or maintain the transistors of the chain in an on state to couple the number of word lines to the voltage line supplied with the inactive voltage via the terminating transistor.
